(19) United States
(12) Patent Application Publication
(10) Pub. No.: US 2025/0344389 A1
(43) Pub. Date: Nov. 6, 2025

(54) MICROELECTRONIC DEVICES INCLUDING CONTACT STRUCTURES AND INTERCONNECT STRUCTURES, AND RELATED METHODS

(71) Applicant: Micron Technology, Inc., Boise, ID (US)

(72) Inventors: Rajasekhar Venigalla, Boise, ID (US); Tom George, Boise, ID (US); Jordan D. Greenlee, Boise, ID (US)

(21) Appl. No.: 19/097,379

(22) Filed: Apr. 1, 2025

Related U.S. Application Data
(60) Provisional application No. 63/641,300, filed on May 1, 2024.

(51) Int. Cl. H10B 43/27; H10B 41/10; H10B 41/27; H10B 43/10

(52) U.S. Cl. CPC H10B 43/27; H10B 41/10; H10B 41/27; H10B 43/10

(57) ABSTRACT

A microelectronic device comprises a source material adjacent to tiers of alternating conductive materials and dielectric materials. Interconnect structures extend through the tiers and into the source material. The interconnect structures comprises a dielectric liner adjacent to the tiers and the source material, a first interconnect liner adjacent to the dielectric liner, and a conductive fill material extending between opposing surfaces of the first interconnect liner. Contact structures within the source material are electrically coupled to the interconnect structures and the contact structures comprise a conductive barrier material adjacent to the interconnect structures, a metal nitride material adjacent to the conductive barrier material, and a conductive contact material adjacent to the metal nitride material. The conductive fill material of the interconnect structures is in electrical contact with the conductive barrier material of the contact structures. Additional microelectronic devices and methods of forming the microelectronic devices are disclosed.

### CROSS-REFERENCE TO RELATED APPLICATIONS

This application claims the benefit under 35 U.S.C. § 119(e) of U.S. Provisional Patent Application Ser. No. 63/641,300, filed May 1, 2024, the disclosure of which is hereby incorporated herein in its entirety by this reference.

### TECHNICAL FIELD

Embodiments disclosed herein relate to microelectronic devices and microelectronic device fabrication. More particularly, embodiments of the disclosure relate to microelectronic devices including a low-resistivity and increased electrical performance contact structure having little or no intervening material between conductive materials of interconnect structures and conductive contact materials of the contact structures, and to related methods.

### BACKGROUND

Memory devices provide data storage for electronic systems. A Flash memory device is one of various memory device types and has numerous uses in modern computers and other electrical devices. A conventional Flash memory device includes a memory array that has a large number of charge storage devices (e.g., memory cells, such as non-volatile memory cells) arranged in rows and columns. In a NAND architecture type of Flash memory, memory cells arranged in a column are coupled in series, and a first memory cell of the column is coupled to a data line (e.g., a bit line). In a three-dimensional NAND (3D NAND) memory device, a type of vertical memory device, not only are the memory cells arranged in row and column fashion in a horizontal array, but tiers of the horizontal arrays are stacked (e.g., vertically stacked) over one another to provide a three-dimensional array of the memory cells. The tiers include alternating conductive materials with insulating (e.g., dielectric) materials. The conductive materials function as control gates for, e.g., access lines (e.g., word lines) of the memory cells. Vertical structures (e.g., pillars including channel materials) extend along the vertical string of the memory cells. A drain end of a string is adjacent to one of the top and bottom of the vertical structure (e.g., pillar), while a source end of the string is adjacent to the other of the top and bottom of the pillar. The drain end is operably connected to a bit line, while the source end is operably connected to a source line. 3D NAND memory devices also include electrical connections between the access lines and other conductive structures of the device so that the memory cells of the vertical strings can be selected for writing, reading, and erasing operations. String drivers drive the access line voltages to write to or read from the memory cells of the vertical string. 3D NAND memory devices may also include multiple decks, one or more decks including one or more memory devices, which may overly a complementary metal-oxide semiconductor (CMOS) region, such as a CMOS under array (CUA) region.

As memory density increases in the 3D NAND memory devices, interconnect structures may be fabricated to minimize signal delay and to optimize packing density. Increased aspect ratios of interconnects (e.g., the length of the interconnect versus the width of the interconnect opening) also occurs. The reliability and performance of integrated circuits may be affected by the quality of the interconnect structures, their contacts, and amounts of resistance between them. However, as the aspect ratios of interconnects increases, possibilities for misalignment, voids, and reduced conductive connectivity also increases.

### BRIEF DESCRIPTION OF THE DRAWINGS

For a detailed understanding of the present disclosure, reference should be made to the following detailed description, taken in conjunction with the accompanying drawings, in which like elements have generally been designated with like numerals, and wherein:

FIG. 1A is a partial top view of a microelectronic device structure including interconnect structures and dielectric liners, in accordance with embodiments of the disclosure.

FIG. 1B is a partial, cross-sectional view of some embodiments of the interconnect structures and contact structures of the microelectronic device structure of FIG. 1A.

FIG. 1C is a partial, cross-sectional view of other embodiments of the interconnect structures and contact structures of the microelectronic device structure of FIG. 1A.

FIGS. 2A through 2D are enlarged, partial, cross-sectional views of fabrication stages during the process of forming the interconnect structures proximal to the contact structures of embodiments of the microelectronic device structure of FIG. 1B.

FIG. 2E is an enlarged, partial, cross-sectional view of the interconnect structures and the contact structures of the embodiments of the microelectronic device structure of FIG. 1B.

FIGS. 2-1A through 2-1D are enlarged, partial, cross-sectional views of fabrication stages during the process of forming the interconnect structures proximal to the contact structures of embodiments of the microelectronic device structure of FIG. 1B.

FIG. 2-1E is an enlarged, partial, cross-sectional view of the interconnect structures and the contact structures of the embodiments of microelectronic device structure of FIG. 1B.

FIGS. 2-2A and 2-2B are enlarged, partial, cross-sectional views of fabrication stages during the process of forming the interconnect structures proximal to the contact structures of embodiments of the microelectronic device structure of FIG. 1B.

FIG. 2-2C is an enlarged, partial, cross-sectional view of the interconnect structures and the contact structures of the embodiments of the microelectronic device structure of FIG. 1B.

FIGS. 2-3A and 2-3B are enlarged, partial, cross-sectional views of fabrication stages during the process of forming the interconnect structures proximal to the contact structures of embodiments of the microelectronic device structure of FIG. 1B.

FIG. 2-3C is an enlarged, partial, cross-sectional view of the interconnect structures and the contact structures of the embodiments of microelectronic device structure of FIG. 1B.

FIGS. 3A through 3D are enlarged, partial, cross-sectional views of fabrication stages during the process of forming the interconnect structures proximal to the contact structures of embodiments of the microelectronic device structure of FIG. 1C.

FIG. 3E is an enlarged, partial, cross-sectional view of the interconnect structures and the contact structures of the embodiments of microelectronic device structure of FIG. 1C.

FIGS. 3-1A through 3-1D are enlarged, partial, cross-sectional views of fabrication stages during the process of forming the interconnect structures proximal to the contact structures of embodiments of the microelectronic device structure of FIG. 1C.

FIG. 3-1E is an enlarged, partial, cross-sectional view of the interconnect structures and contact structures of the embodiments of microelectronic device structure of FIG. 1C.

FIGS. 3-2A through 3-2C are enlarged, partial, cross-sectional views of fabrication stages during the process of forming the interconnect structures proximal to the contact structures of embodiments of the microelectronic device structure of FIG. 1C.

FIG. 3-2D is an enlarged, partial, cross-sectional view of the interconnect structures and contact structures of the embodiments of microelectronic device structure.

FIGS. 3-3A through 3-3C are enlarged, partial, cross-sectional views of fabrication stages during the process of forming the interconnect structures proximal to the contact structures of embodiments of the microelectronic device structure of FIG. 1C.

FIG. 3-3D is an enlarged, partial, cross-sectional view of the interconnect structures and the contact structures of the embodiments of microelectronic device structure of FIG. 1C.

FIG. 4 is a diagrammatic cross-sectional side view of a multi-deck assembly, in accordance with embodiments of the disclosure.

FIG. 5 is a simplified, partial, cutaway perspective view of a microelectronic device, in accordance with embodiments of the disclosure.

FIG. 6 is a schematic block diagram illustrating a microelectronic system, in accordance with embodiments of the disclosure.

### DETAILED DESCRIPTION

A microelectronic device (e.g., an apparatus, an electronic device, a portion of an electronic device, a semiconductor device, a memory device, etc.) is disclosed that includes a microelectronic device structure having an interconnect structure that exhibits a reduced electrical resistance relative to a contact structure of the microelectronic device structure. The materials of the interconnect structure are formed within an interconnect opening and adjacent to a dielectric liner and include a conductive fill material and an interconnect liner. As a thickness of the interconnect liner relative to a critical dimension (CD) of the interconnect opening increases, a probability of increased electrical interference in the microelectronic device increases. In other words, as the thickness of the interconnect liner increases relative to a volume of the conductive fill material in the interconnect opening, electrical interference in the microelectronic device increases. To offset increasing electrical interference, electrical resistivities of materials of the interconnect structure relative to materials of the contact structure are reduced. For example, the interconnect structure may be formed in an array region of the microelectronic device structure and comprises two or more materials, such as a material of the interconnect liner having a relatively higher electrical resistivity than a material of the conductive fill material of the interconnect structure. The contact structure may be formed in a source material of the microelectronic device structure and comprises two or more materials, such as a dielectric film material having a higher electrical resistivity than a metal material of the contact structure. To improve electrical performance, forming the interconnect structure and the contact structure of the microelectronic device structure includes removing a portion of the first interconnect material (e.g., the liner, or the higher electrical resistivity material) from intervening between the interconnect metal material (e.g., the fill, or the lower electrical resistivity material) and the metal contact material (i.e., lower electrical resistivity material) of the contact structure.

In some embodiments, a bottom portion of an interconnect liner may be selectively removed to expose the metal contact material of the contact structure, such that when the metal fill material of the interconnect structure is deposited, a portion directly contacts the metal contact material of the contact structure. In other embodiments, an amount of interconnect liner directly contacting the metal contact material of the contact structure is reduced (i.e., relative to conventional contact structures), such that an overall electrical resistivity relative to the contact structure is reduced. Reducing overall electrical resistivity increases the memory array performance (e.g., tWR—recovery write time).

The following description provides specific details, such as material types, material thicknesses, and process conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the semiconductor industry. In addition, the description provided herein does not form a complete description of a microelectronic device or a complete process flow for manufacturing the microelectronic device and the structures described below do not form a complete microelectronic device. Only those process acts and structures necessary to understand the embodiments described herein are described in detail below. Additional acts to form a complete microelectronic device may be performed by conventional techniques.

Drawings presented herein are for illustrative purposes only and are not meant to be actual views of any particular material, component, structure, microelectronic device, or microelectronic system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, the singular forms of the terms “a,” “an,” and “the” are intended to include the plural forms as well, unless the context clearly indicates otherwise.

As used herein, the terms “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, the term “and/or” includes any and all combinations of one or more of the associated listed items.

As used herein, the term “array region” means and includes a region of a microelectronic device including memory cells of a memory array. The array region of the microelectronic device includes active circuitry.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the term “configured” refers to a size, shape, material composition, and arrangement of one or more of at least one structure and at least one apparatus facilitating operation of one or more of the structure and the apparatus in a pre-determined way.

As used herein, the phrase “coupled to” refers to structures operatively connected with each other, such as electrically connected through a direct ohmic connection or through an indirect connection (e.g., by way of another structure).

As used herein, the term “microelectronic device” includes, without limitation, an electronic device, such as a memory device, as well as a semiconductor device which may or may not incorporate memory, such as a logic device, a processor device, or a radiofrequency (RF) device. Further, a microelectronic device may incorporate memory in addition to other functions such as, for example, a so-called “system on a chip” (SoC) including a processor and memory, or a microelectronic device including logic and memory. The microelectronic device includes tiers of alternating conductive materials and dielectric materials.

As used herein, the term “microelectronic device structure” means and includes a precursor structure to the microelectronic device.

As used herein, the term “multi-deck assembly” means and includes one or more stacks connected to at least another microelectronic device structure. The at least another stack or the at least another microelectronic device structure may be integrated to form a memory device, or may comprise a portion of the memory device, such as a CMOS device including control logic or circuitry.

As used herein, the term “non-array region” means and includes a region of the microelectronic device proximal to the array region.

As used herein, reference to an element as being “on” or “over” another element means and includes the element being directly on top of, adjacent to (e.g., laterally adjacent to, vertically adjacent to), underneath, or in direct contact with the other element. It also includes the element being indirectly on top of, adjacent to (e.g., laterally adjacent to, vertically adjacent to), underneath, or near the other element, with other elements present therebetween. In contrast, when an element is referred to as being “directly on” or “directly adjacent to” another element, no intervening elements are present.

As used herein, the term “selectively etchable” means and includes a material that exhibits a greater etch rate responsive to exposure to a given etch chemistry and/or etch conditions relative to another material exposed to the same etch chemistry and/or etch conditions. For example, the material may exhibit an etch rate that is at least about five times greater than the etch rate of another material, such as an etch rate of about ten times greater, about twenty times greater, or about forty times greater than the etch rate of the another material. Etch chemistries and etch conditions for selectively etching a desired material may be selected by a person of ordinary skill in the art.

As used herein, the term “selectively removable” means and includes a material that exhibits a greater removal rate responsive to exposure to a removal chemistry and/or removal conditions, collectively referred to herein as process conditions, relative to another material exposed to the same removal chemistry and/or removal conditions. A material that is selectively removable relative to another material is substantially completely removable without removing substantially any of the another material.

As used herein, the term “stack” means and includes multiple (e.g., two or more) tiers of alternating nitride materials and dielectric materials (e.g., relative to a microelectronic device structure) or alternating conductive materials and dielectric materials (e.g., relative to a microelectronic device).

As used herein, the term “step” means and includes an offset between sidewalls of vertically adjacent materials. For instance, the sidewalls of one of the materials of the vertically adjacent materials are not substantially aligned with the sidewalls of the other material.

As used herein, the term “substantially” in reference to a given parameter, property, or condition means and includes to a degree that one of ordinary skill in the art would understand that the given parameter, property, or condition is met with a degree of variance, such as within acceptable manufacturing tolerances. By way of example, depending on the particular parameter, property, or condition that is substantially met, the parameter, property, or condition may be at least 90.0% met, at least 95.0% met, at least 99.0% met, or even at least 99.9% met.

As used herein, the term “substrate” means and includes a material (e.g., a base material) or construction upon which additional materials are formed. The substrate may be a microelectronic substrate, a semiconductor substrate, a base semiconductor layer on a supporting structure, an electrode, an electronic substrate having one or more materials, layers, structures, or regions formed thereon, or a semiconductor substrate having one or more materials, layers, structures, or regions formed thereon. The materials on the microelectronic substrate or semiconductor substrate may include, but are not limited to, semiconductive materials, insulating materials, conductive materials, etc. The substrate may be a conventional silicon substrate or other bulk substrate comprising a layer of semiconductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

As used herein, the terms “vertical,” “longitudinal,” “horizontal,” and “lateral” are in reference to a major plane of a structure and are not necessarily defined by Earth's gravitational field. A “horizontal” or “lateral” direction is a direction that is substantially parallel to the major plane of the structure, while a “vertical” or “longitudinal” direction is a direction that is substantially perpendicular to the major plane of the structure (e.g., parallel to the Z-axis). The major plane of the structure is defined by a surface of the structure having a relatively large area compared to other surfaces of the structure. The height of a respective material or feature (e.g., structure) may be defined as a dimension in a vertical plane.

The following description provides specific details, such as material types and processing conditions, in order to provide a thorough description of embodiments of the disclosed apparatus (e.g., devices, systems) and methods. However, a person of ordinary skill in the art will understand that the embodiments of the apparatus and methods may be practiced without employing these specific details. Indeed, the embodiments of the apparatus and methods may be practiced in conjunction with conventional semiconductor fabrication techniques employed in the industry.

Unless the context indicates otherwise, the materials described herein may be formed by any suitable technique including, but not limited to, spin coating, blanket coating, chemical vapor deposition (“CVD”), atomic layer deposition (“ALD”), plasma enhanced ALD, physical vapor deposition (“PVD”) (e.g., sputtering), or epitaxial growth. Depending on the specific material to be formed, the technique for depositing or growing the material may be selected by a person of ordinary skill in the art. Unless the context indicates otherwise, the removal of materials described herein may be accomplished by any suitable technique including, but not limited to, etching (e.g., dry etching, wet etching, vapor etching), ion milling, abrasive planarization, or other known methods.

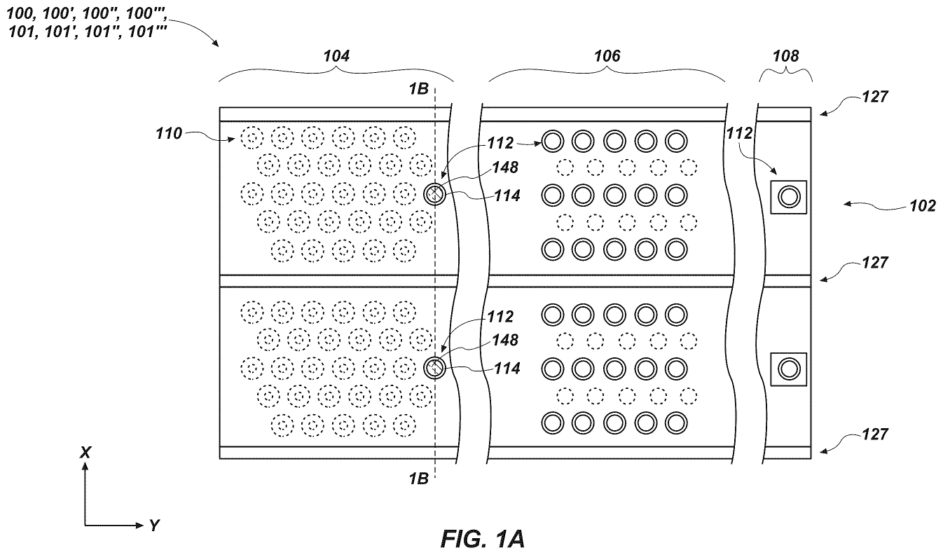

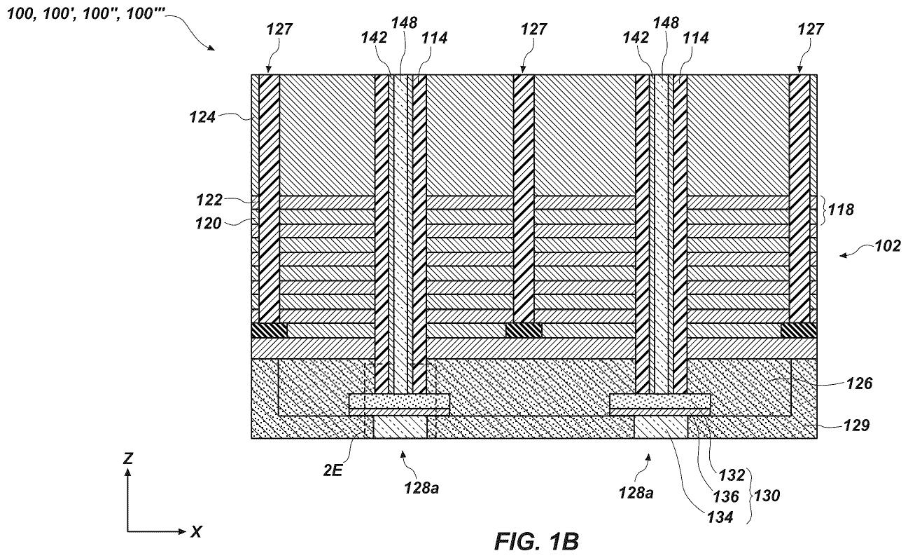

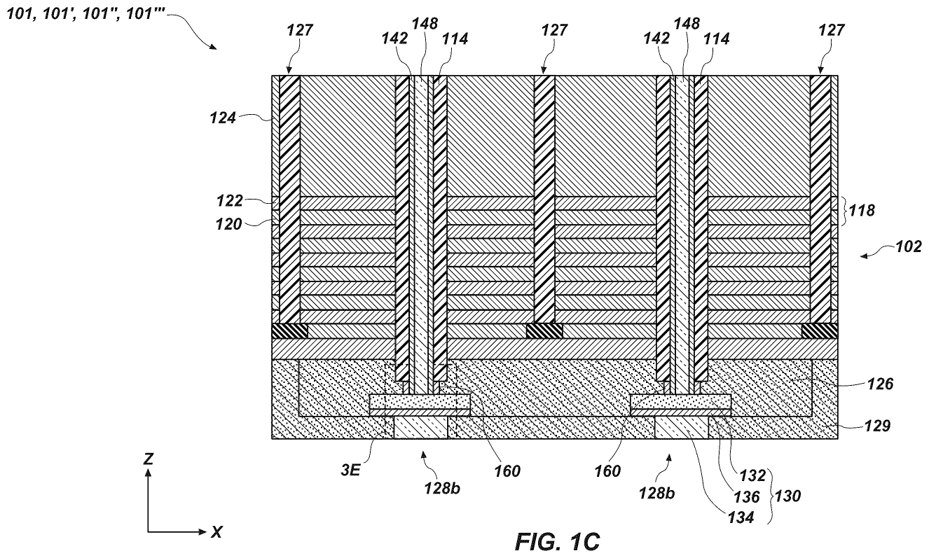

A top view of a microelectronic device structure 100, 100′, 100″, 100′″ that includes one or more stacks 102, a memory array region 104, an edge of array (EOA) region 106, and a periphery region 108 is depicted in FIG. 1A. The stack 102 includes alternating dielectric and conductive materials. The EOA region 106 and the periphery region 108 constitute a non-array region of the microelectronic device structure 100. The memory array region 104 includes memory cell pillars 110 that form strings of memory cells arranged in columns, and interconnect structures 112 having one or more liner materials, such as dielectric liner 114. The interconnect structures 112 may, for example, include the dielectric liner 114, a first interconnect liner 142, and a conductive fill material 148. A material of the interconnect structures 112 may exhibit a lower electrical resistivity than other of the materials of the interconnect structures 112. Although the memory array region 104 of the microelectronic device structure 100, 100′, 100″, 100′″ is depicted as having the interconnect structures 112, the EOA region 106 and the periphery region 108 may also include additional interconnect structures 112, having the dielectric liner 114, additional liner materials, or fewer liner materials.

To form the microelectronic device structure 100, 100′, 100″, 100′″, tiers (not shown) of nitride materials and dielectric materials are formed, with the nitride materials subsequently replaced with conductive materials using slits 127 as part of a so-called “replacement gate” (RG) or “gate last” process. The nitride materials of the tiers may be removed by exposing the nitride materials to a wet etchant comprising one or more of phosphoric acid, sulfuric acid, hydrochloric acid, nitric acid, or another etch chemistry, such as a so-called “wet nitride strip” comprising a wet etchant comprising phosphoric acid. Tiers 118 of alternating conductive materials 120 and dielectric materials 122 are subsequently formed by forming the conductive materials 120 in spaces resulting from the removed nitride materials. After the RG process, the slits 127 may be filled with a dielectric or insulation material. Although the slits 127 are depicted as formed along a length, or parallel with the y-axis, of the microelectronic device structure 100, 100′, 100″, 100′″, in other embodiments, the slits 127 may be formed along a width, or parallel to the x-axis.

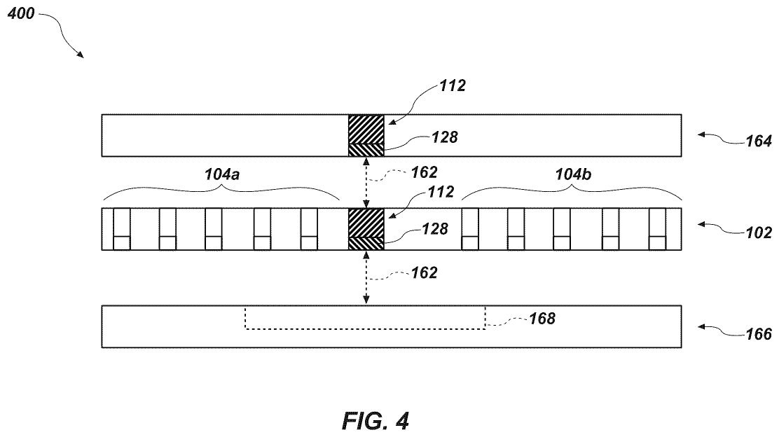

The interconnect structure 112 may be formed after conducting the RG process, and before the microelectronic device structure 100, 100′, 100″, 100′″ is electrically connected to additional decks of a multi-deck assembly (see FIG. 4). Alternatively, the interconnect structure 112, or at least a portion thereof, may be formed before the RG process.

Referring to FIGS. 1A and 1B, the dielectric liner 114 may be formed on sidewalls and bottom surfaces of an interconnect opening 116, which may have been formed in the tiers 118 of the alternating conductive materials 120 and dielectric materials 122 (e.g., through use of a conventional patterned mask material formation and a selective etch process). The interconnect opening 116 may be a high aspect ratio (HAR) opening. For example, the AR of the interconnect opening 116 may be 5:1, 10:1, 15:1, 20:1, 30:1, 40:1, 50:1, 60:1, 70:1, 80:1, 90:1, 100:1, 200:1, or more. In some embodiments, the AR of the interconnect opening 116 may be from about 10:1 to about 30:1. The dielectric liner 114, the first interconnect liner 142, and the conductive fill material 148 are formed in the interconnect opening 116. The dielectric liner 114 may be conformally formed along an exposed surface of a conductive barrier material 132 and on sidewalls of the tiers 118 of the alternating conductive materials 120 and dielectric materials 122 by an ALD process, or by a CVD process. The dielectric liner 114 may be formed to surround, annularly, or be laterally adjacent to and vertically adjacent to (e.g., at the bottom surface of the interconnect opening 116) the materials that define the interconnect openings 116. During formation of the microelectronic device structure 100, 100′, 100″, 100′″, the dielectric liner 114 may form a substantially continuous material over a cap dielectric material 124, portions of which may be removed (e.g., portions that are outside or above the interconnect openings 116) through a chemical or mechanical material removal process, such as a chemical mechanical polishing (CMP) planarization process.

Although FIG. 1A depicts the interconnect structures 112 as circular (i.e., top view of right-cylindrical structures) and having annular-shaped portions of the dielectric liner 114, and FIGS. 1B and 1C depict the materials of the interconnect structures 112 (e.g., dielectric liner 114 and fill material 148) as having a rectangular shape, other shapes and configurations are contemplated and included herein. For example, the interconnect structures 112 may be configured to have square, triangular, rectangular, trapezoidal, annular, ellipsoidal, or truncated shapes. In some embodiments, the interconnect structure 112 may exhibit a right-cylindrical shape, having an annular shape of the dielectric liner 114 surrounding, or partially surrounding an inner circumference of the right-cylindrical shape.

The dielectric liner 114 may be a stress compensation material, such as a silicon oxide material (e.g., SiO_{y}). In some embodiments, the dielectric liner 114 is a high-quality ALD SiOₓ material. In other embodiments, the dielectric liner 114 is a uniform and conformal ALD silicon oxide material (e.g., a conformal SiO₂ material). The dielectric liner 114 may exhibit a relatively higher electrical resistivity than other materials of the interconnect structure 112 (e.g., higher than the first interconnect liner 142 and the conductive fill material 148). The dielectric liner 114 may be from about 70 nanometers to about 100 nanometers in thickness, such as from about 80 nanometers to about 90 nanometers in thickness, or from about 83 to about 87 nanometers in thickness.

The stacks 102 of the microelectronic device structure 100, 100′, 100″, 100′″ include the tiers 118 of the alternating conductive materials 120 and dielectric materials 122 formed adjacent to (e.g., vertically adjacent to, over) a conductive material of a source material 126 adjacent to (e.g., on) a substrate (not shown). The source material 126 is formed vertically adjacent to additional insulation material 129 and the substrate by conventional techniques. The alternating conductive materials 120 and dielectric materials 122 of the tiers 118 are formed adjacent to (e.g., vertically adjacent to, or on) the source material 126 by conventional techniques. For example, the multiple tiers 118 of alternating conductive materials 120 and dielectric materials 122 may be formed from alternating nitride materials (not shown) and dielectric materials. The nitride material may be, for example, a silicon nitride (SiN_{y}). The dielectric materials 122 may be an electrically insulative material. By way of non-limiting example, the dielectric materials 122 may be formed of and include a dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and a MgOₓ), a dielectric oxynitride material (e.g., SiOₓN_{y}), a dielectric oxycarbide material (e.g., SiOₓC_{y}), a hydrogenated dielectric oxycarbide material (e.g., SiCₓOyH_{z}), or a dielectric carboxynitride material (e.g., SiOₓCzN_{y}). In some embodiments, the dielectric material 122 is SiOₓ. The dielectric material 122 may be configured to electrically isolate conductive materials. In some embodiments, the source material 126 is a polysilicon material.

The cap dielectric material 124 may have the same material composition as the dielectric material 122 or a different material composition than the dielectric material 122. For instance, the cap dielectric material 124 and the dielectric materials 122 may be formed of different materials (e.g., different material compositions) having sufficiently different etch rates. Alternatively, the cap dielectric material 124 and the dielectric materials 122 may be formed of similar materials (e.g., similar material compositions) by different techniques that result in the materials having sufficiently different etch rates to be selectively etchable relative to one another or to other materials of the microelectronic device structure 100, 100′, 100″, 100′″. By way of non-limiting example, the cap dielectric material 124 may be formed of and include a silicon oxide, a silicon oxycarbide, or a silicon oxynitride. The cap dielectric material 124 may be doped or undoped to achieve the desired etch selectivity relative to the dielectric materials 122. In some embodiments, the cap dielectric material 124 is formed of and includes silicon dioxide. The cap dielectric material 124 may be homogeneous in material composition or may be heterogeneous in material composition.

The cap dielectric material 124 may include a sacrificial material (not shown) at an upper portion thereof to form a bonding surface for bonding another microelectronic device structure above the microelectronic device structure 100, 100′, 100″, 100′″, such as another microelectronic device structure (e.g., second deck 164, see FIG. 4) or a CMOS structure for a CMOS over array (“CoA”) device (not shown). The sacrificial material may be substantially the same material composition as the cap dielectric material 124, or the material composition of the sacrificial material may be different than the composition of the cap dielectric material 124. In some embodiments, the sacrificial material may overlie horizontal boundaries of each of the regions 104, 106, and 108. In addition, the substrate or the source material 126 may include a sacrificial material for bonding another microelectronic device structure to the bottom of the microelectronic device structure 100, 100′, 100″, 100′″.

Contact structures 128a, 128b (collectively referred to herein as contact structures 128) are located adjacent to (e.g., below) an end of the interconnect structures 112. The contact structures 128 are electrically coupled to the interconnect structures 112. The contact structures 128 may be located below the tiers 118 and may be formed of and include multiple contact materials 130, such as an optional conductive barrier material 132, a conductive contact material 134, and a metal nitride material 136. One or more of the contact materials 130 may exhibit a higher electrical resistivity than other of the contact materials 130. In some embodiments, the conductive barrier material 132, if present, has a higher electrical resistivity than the conductive contact material 134. In some embodiments, the contact structures 128 are configured as select line conductive contact structures 128a.

The conductive barrier material 132 may be a conductive material that has higher electrical resistivity than the conductive contact material 134. For example, the conductive barrier material 132 may include a conductive metal nitride, a conductive metal silicide, or a conductively doped semiconductor material. By way of non-limiting example, the conductive barrier material 132 may be formed of and include one or more of tungsten (W), tungsten nitride (WN_{y}), nickel (Ni), tantalum (Ta), tantalum nitride (TaN_{y}), tantalum silicide (TaSiₓ), platinum (Pt), copper (Cu), silver (Ag), gold (Au), aluminum (Al), molybdenum (Mo), titanium (Ti), titanium nitride (TiN_{y}), titanium silicide (TiSiₓ), tungsten silicide (WSiₓ), titanium silicon nitride (TiSiₓN_{y}), titanium aluminum nitride (TiAlₓN_{y}), molybdenum nitride (MoNₓ), iridium (Ir), iridium oxide (IrO_{z}), ruthenium (Ru), ruthenium oxide (RuO_{z}), polysilicon, and conductively doped silicon (where x, y, and z include stoichiometric and non-stoichiometric amounts of the components). In some embodiments, the conductive barrier material 132 is a tungsten silicide (e.g., WSiₓ), which has an electrical resistivity of from about 60 μΩ·cm to about 80 μΩ·cm.

The conductive barrier material 132 may be optional, depending on materials used to form the contact structures 128 and the interconnect structures 112. In some embodiments, the conductive barrier material 132 is present to reduce or prevent diffusion or electrical leakage from a conductive material (e.g., copper) of the interconnect structure 112.

The conductive contact material 134 may include any suitable conductive material having a relatively low electrical resistivity relative to other of the contact materials 130. The conductive contact material 134 may include one or more metals (e.g., titanium, tungsten, cobalt, nickel, platinum, ruthenium, etc.); metal-containing compounds (e.g., metal silicide metal nitride, metal carbide, etc.); and/or conductively doped semiconductor materials (e.g., conductively doped silicon, conductively doped germanium, etc.). For example, the conductive contact material 134 may have the lowest electrical resistivity relative to the other contact materials 130 of the contact structures 128 and less than or equal to the electrical resistivity of the conductive fill material of the interconnect structures 112. In some embodiments, the conductive contact material 134 is tungsten, which has an electrical resistivity of from about 5.0 E-4 μΩ·cm to about 6.0 E-4 μΩ·cm.

The metal nitride material 136 may have an electrical resistivity that is relatively higher than the electrical resistivity of the conductive contact material 134. By way of a non-limiting example, the metal nitride material 136 may be titanium nitride (TiN_{y}), boron nitride (BN_{y}), germanium nitride (GeN_{y}), aluminum nitride (AlN_{y}), or molybdenum nitride (MoNₓ), where each of x, y, z is independently an integer or a non-integer. Alternatively, the metal nitride material 136 may be a carbonitride material (e.g., silicon carbonitride (SiC_{z}N_{y})), where each of x, y, z is independently an integer or a non-integer. The metal nitride material 136 may be a binary or multinary (e.g., ternary) compound. The material of the metal nitride material 136 may be the same as, or different than, the material of the conductive barrier material 132. In some embodiments, the metal nitride material 136 is titanium nitride (TiN_{y}), which has an electrical resistivity of about 25 μΩ·cm.

Referring to FIG. 1C, contact structures 128b of a microelectronic device structure 101, 101′, 101″, 101′″ are similar to contact structures 128a and include multiple contact materials 130, such as the optional conductive barrier material 132, the conductive contact material 134, and the metal nitride material 136. The contact structures 128b differ from the contact structures 128a in that at least a portion of the source material 126 intervenes between a bottom surface (e.g., vertically) of the dielectric liner 114 and a top surface of the conductive barrier material 132. The contact structures 128b also differ from the contact structures 128a by the presence of an additional material, such as a conductive coating material 160, adjacent to the source material 126. The formation of the contact structures 128b and the contact structures 128a may also differ. In some embodiments, the contact structures 128 are configured as access line conductive contact structures 128b.

In some embodiments, the dielectric liner 114 is silicon oxide, the source material 126 is polysilicon, the first interconnect liner 142 is titanium nitride, the conductive fill material 148 is tungsten, the conductive barrier material 132 is tungsten silicide, the conductive contact material 134 is tungsten, and the metal nitride material 136 is titanium nitride.

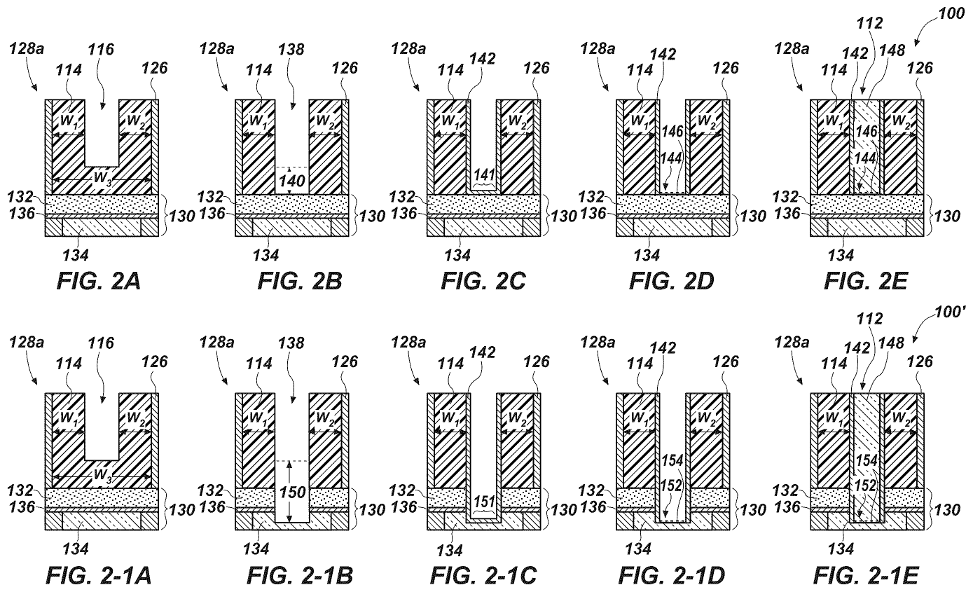

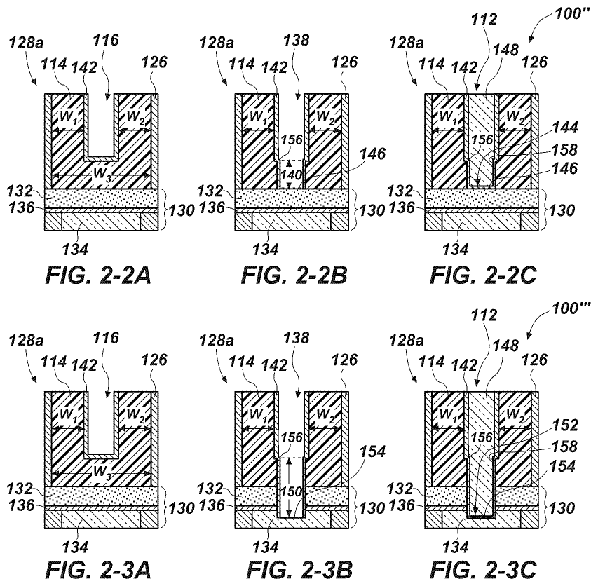

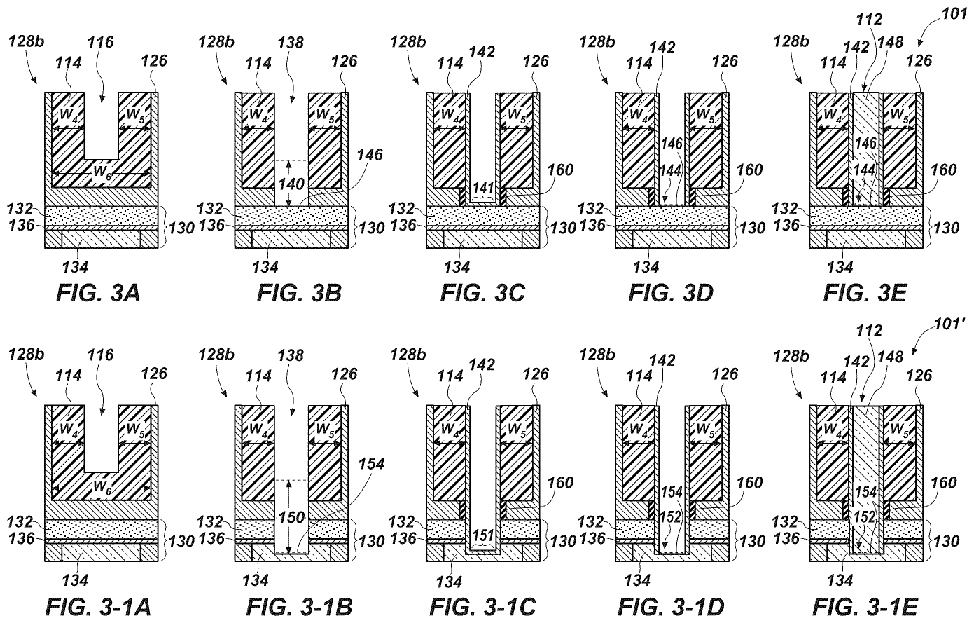

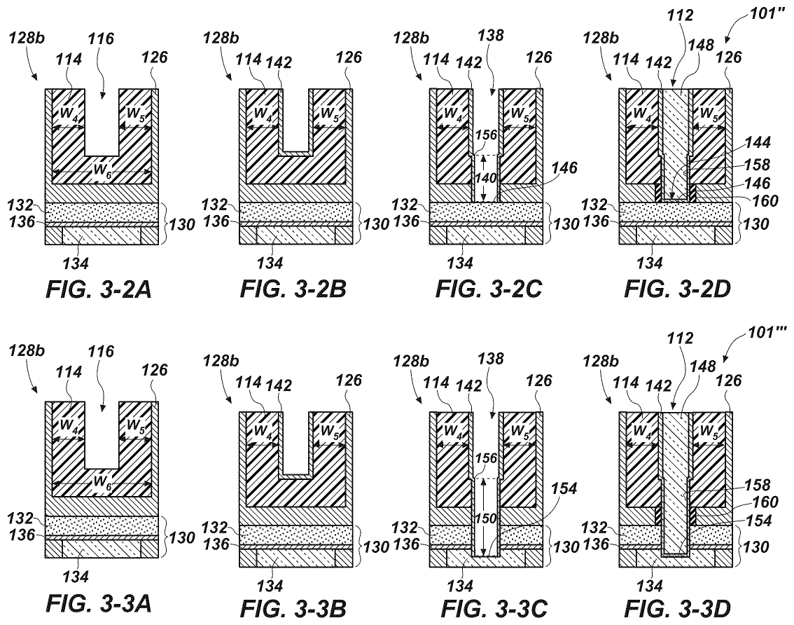

The microelectronic device structures 100, 100′, 100″, 100′″, 101, 101′, 101″, 101′″ may also differ in the interconnect structures 112. For instance, the interconnect structures 112 may differ in one or more of an extent (e.g., a depth) to which the conductive fill material 148 extends into surrounding materials or a diameter (e.g., width) of the conductive fill material 148. By way of example only, the conductive fill material 148 may extend to, but not through, the conductive barrier material 132, as shown in FIG. 1B. Alternatively, the conductive fill material 148 may extend through the conductive barrier material 132 and into the conductive contact material 134, as shown in FIG. 1C. The conductive fill material 148 may exhibit a substantially uniform diameter along its depth (see FIGS. 1B, 1C) or may exhibit a changing (e.g., non-uniform) diameter along its depth (see FIGS. 2-2C, 2-3C, FIGS. 3-2D, 3-3D). The interconnect structures 112 may be electrically coupled to the contact structures 128.

The microelectronic device structures 100, 100′, 100″, 100′″, 101, 101′, 101″, 101′″ including the interconnect structures 112 and the contact structures 128a, 128b according to embodiments of the disclosure, may provide increased electrical performance to electronic devices containing the interconnect structures 112 and the contact structures 128. Relative dimensions of the materials of the interconnect structures 112 and the contact structures 128a, 128b may be reduced (e.g., reduced in size) without decreasing electrical performance of the electronic devices. The reduced dimensions of the materials of the interconnect structures 112 may be relative to dimensions of conventional interconnect structures and conventional contact structures. The conductive fill material 148 may be in direct contact with the conductive barrier material 132 or the conductive contact material 134, in comparison to conventional interconnect structures where an interconnect liner separates the interconnect structures from conductive materials of the conventional electronic devices. Since the conductive fill material 148 has a relatively lower electrical resistivity compared to the electrical resistivity of the first interconnect liner 142, the interconnect structures 112 and the contact structures 128a, 128b provide increased electrical performance to the microelectronic device structures 100, 100′, 100″, 100′″, 101, 101′, 101″, 101′″. In some embodiments, the conductive fill material 148 exhibits the lowest electrical resistivity out of the materials of the interconnect structure 112. Therefore, the conductive fill material 148 may be in direct contact with a material (e.g., the conductive barrier material 132, the conductive contact material 134) that has less electrical resistivity relative to the first interconnect liner 142.

FIGS. 2A through 2E, FIGS. 2-1A through 2-1E, FIGS. 2-2A through 2-2C, and FIGS. 2-3A through 2-3C are partial, cross-sectional views of embodiments of contact structures 128a and interconnect structures 112 depicted at various stages during the process of forming embodiments of the microelectronic device structure 100, 100′, 100″, 100′″. FIGS. 2A through 2E, FIGS. 2-1A through 2-1E, FIGS. 2-2A through 2-2C, and FIGS. 2-3A through 2-3C are enlargements of the portion of the microelectronic device structure 100, 100′, 100″, 100′″ indicated by the dashed box in FIG. 1B. FIGS. 2A through 2D, FIGS. 2-1A through 2-1D, FIGS. 2-2A through 2-2B, and FIGS. 2-3A through 2-3B illustrate earlier process acts and FIGS. 2E, 2-1E, 2-2C, and 2-3C illustrate the microelectronic device structure 100, 100′, 100″, 100′″ including the contact structures 128a and the interconnect structures 112 in relation to the source material 126. The contact materials 130 of the contact structure 128a, including the conductive barrier material 132, the conductive contact material 134, and the metal nitride material 136, are shown in relation to the dielectric liner 114, the conductive fill material 148, and the first interconnect liner 142 of the interconnect structures 112.

Referring to FIG. 2A, the dielectric liner 114 is formed (e.g., conformally formed) in a first interconnect opening 116 and has a first lateral thickness, W₁, a second lateral thickness, W₂, and a third lateral thickness, W₃, where W₃ is substantially equal to a CD of the first interconnect opening 116. W₁ and W₂ may be substantially equal to one another and W₃ may be greater than W₁ or W₂. The dielectric liner 114 is formed on opposite sidewalls of the tiers 118 and source material 126 through which the first interconnect opening 116 extends and partially fills the first interconnect opening 116. As the thickness of the dielectric liner 114 relative to the CD of the first interconnect opening 116 (e.g., W₃) increases, a higher probability exists of reduced electrical connectivity between an interconnect structure 112 and a contact structure 128. To compensate for the reduced electrical connectivity, portions of materials that intervene between a conductive fill material 148 (see FIG. 2E) of the interconnect structure 112 and a lower electrical resistivity material of the contact materials 130 of the contact structure 128a are selectively removed, as described in detail below.

Referring to FIG. 2B, a first material removal act is conducted and selectively removes a bottom portion of the dielectric liner 114, extending a depth of the first interconnect opening 116 and forming a second interconnect opening 138. The first material removal act removes horizontally oriented portions of the dielectric liner 114, exposing the conductive barrier material 132, if present, without substantially removing the dielectric liner 114 on the sidewalls of the tiers 118 and source material 126 and without substantially removing the conductive barrier material 132. The second interconnect opening 138 terminates at an upper surface of the conductive barrier material 132. If no conductive barrier material 132 is present, the first material removal act terminates at an upper surface of the metal nitride material 136. A depth 140 may be an additional depth beyond the initial depth of the interconnect opening 116, where the additional depth is substantially equivalent to the thickness of the dielectric liner 114.

The first material removal act includes an etch process, such as a dry etch process, that removes the portion of the dielectric liner 114. The first material removal act may, for example, be a reactive ion etching (RIE) process. Alternatively, the first material removal act may be an in situ, anisotropic wet etch process. The in situ wet etch process may use various etch chemistries depending on material compositions present in the contact structure 128 (e.g., 128a, 128b). For example, the first material removal act may use an etch chemistry formulated to stop on the conductive barrier material 132, as shown in FIGS. 2B and 2-2B, or on the conductive contact material 134, as shown in FIGS. 2-1B and 2-3B.

Referring to FIG. 2C, the first interconnect liner 142 may comprise a conductive material formed (e.g., deposited) along the sidewalls of the dielectric liner 114 and exposed surface of conductive barrier material 132. The first interconnect liner 142 may extend substantially continuously over the sidewalls of the dielectric liner 114 and exposed surface of the conductive barrier material 132. The first interconnect liner 142 may comprise the same material as the metal nitride material 136. Alternatively, the first interconnect liner 142 may comprise a different material than the metal nitride material 136. The first interconnect liner 142 may comprise one or more of Ta, TaSiN, TaN, TiSiN, Ti, TiN, W, WN, Mo, MoN, Co, CoN, WSiN, where the chemical formulas indicate components and not specific stoichiometries. The first interconnect liner 142 may further comprise one or more of boron and argon, such as by using a flow gas during the deposition of the first interconnect liner 142. For example, a boron precursor material, such as B₂H₆, may be provided with precursor materials of the first interconnect liner 142 to enhance nucleation of the conductive fill material 148 subsequently formed onto the first interconnect liner 142.

The first interconnect liner 142 may be formed using one or more conformal deposition techniques, such as one or more of an ALD process or a CVD process. Portions of the first interconnect liner 142 may be subsequently removed. For example, portions of the first interconnect liner 142 that are outside or above the second interconnect opening 138 may be removed through a chemical or mechanical material removal process, such as a CMP planarization process.

Referring to FIG. 2D, a second material removal act is conducted to selectively remove a bottom portion 141 of the first interconnect liner 142. Removing the bottom portion of the first interconnect liner 142 exposes an upper surface 144 of the conductive barrier material 132 if present without substantially removing the first interconnect liner 142 from the sidewalls of the dielectric liner 114 and without substantially removing the conductive barrier material 132. The second material removal act may, optionally, form a native oxide 146 on the upper surface 144 of the conductive barrier material 132. The first interconnect liner 142 remaining on the sidewalls of the dielectric liner 114 has substantially the same thickness (e.g., a uniform thickness) along its length. In other words, the thickness of the first interconnect liner 142 is substantially uniform proximal to the contact materials 130 and distal to the contact materials 130. The native oxide 146 may form depending on the environment in which the second material removal act occurs. For example, when the second material removal act occurs in a controlled, inert environment, little or no native oxide 146 may be formed. Alternatively, when the second material removal act occurs in a non-inert, less-controlled, or less inert environment, the native oxide 146 may form through an oxidation process. The second material removal act may include an etch process, such as a wet etch process, that selectively etches the bottom portion 141 of the first interconnect liner 142 relative to the contact materials 130 of the contact structure 128. For example, the second material removal act may comprise an anisotropic wet etch process, incorporating etchants, such as a combination of ammonium hydroxide (NH₄OH) and water (e.g., deionized). The concentration of the NH₄OH in water may be from about 2 wt % to about 90 wt %. In some embodiments, the etchant may be formed by combining NH₄OH (29 wt % in water) with water. For example, the ratio of water to stock may be about 5:1, about 50:1, about 100:1, about 2000:1, etc.

Referring to FIG. 2E, a conductive fill material 148 is formed in the second interconnect opening 138 directly adjacent to the conductive barrier material 132 or to the native oxide 146 if present. The conductive fill material 148 may also be directly adjacent to the first interconnect liner 142. Therefore, the conductive fill material 148 may be in direct contact with the conductive barrier material 132, the first interconnect liner 142, and, optionally, the native oxide 146. The conductive fill material 148 substantially fills the remaining volume of the second interconnect opening 138. In some embodiments, the conductive fill material 148 comprises the same material composition as the conductive contact material 134. In some embodiments, the conductive fill material 148 is tungsten. The conductive fill material 148 may exhibit substantially the same electrical resistivity or conductivity as the conductive contact material 134. Alternatively, the conductive fill material 148 may exhibit a different electrical resistivity than the conductive contact material 134. Due to the removal of the bottom portion 141 of the first interconnect liner 142, the conductive fill material 148 may directly contact the conductive barrier material 132 or the optional native oxide 146 on the conductive barrier material 132. Removing the bottom portion 141 of the first interconnect liner 142 may prevent or reduce electrically impeding the flow of electrical current from the conductive fill material 148 of the interconnect structure 112 to the contact materials 130 of the contact structure 128a, such as to the conductive barrier material 132. Removing the bottom portion 141 eliminates, for example, a titanium nitride material, in the direct path of current flow.

The conductive fill material 148 may be a high conductivity metal material, a medium conductivity metal material, or a low conductivity metal material, depending on desired performance properties (e.g., capacitance) of the microelectronic device structure 100. The high conductivity metal material may, for example, be copper, the medium conductivity metal material may, for example, be aluminum, and the low conductivity metal material may, for example, be tungsten. The copper may be elemental copper or a copper alloy comprising copper in combination with one or more of C, Ag, Co, Ta, In, Sn, Zn, Mn, Ti, Mg, Cr, Ge, Sr, Pt, Mg, Al, or Zr.

The conductive fill material 148 may be formed by conventional techniques using a metal source gas, including one or more metal precursors. For example, a tungsten precursor may include tungsten hexafluoride (WF₆). By way of another example, an aluminum precursor may be trimethyl aluminum (TMA), triethyl aluminum (TEA), 1-methylpyrrolidine alane (MPA), dimethylethylamine alane (DMEAA) dimethyl aluminum hydride (DMAH), trimethylaminealane borane (TMAAB), and combinations thereof. A titanium precursor may include, but is not limited to, tetrakis(isopropoxide)(Ti(O-iProp)₄), titanium halide, cyclopentadienyl titanium, titanium bis(isopropoxide)-bis(2,2,6,6-tetramethyl-3,5-heptanedionate) (Ti(O-iProp)₂(thd)₂), titanium bis(4-N-(2-methylethoxy)imino-2-pentanoate) (Ti(2meip)2), titanium bis[4-(ethoxy)imino-2-pentanoate](Ti(eip)2), or titanium bis[2,2-dimethyl-5-(2-methylethoxy)imino-3-heptanoate](Ti(22dm2meih)2), a hafnium precursor, such as hafnium t-butoxide (HTB, Hf(OtBu)₄), tetrakis(diethylamido)hafnium (TDEAH, Hf(Net2)₄), tetrakis(ethylmethylamido)hafnium (TEMAH, Hf(NetMe)₄), or tetrakis(dimethylamido)hafnium (TDMAH, Hf(Nme₂)₄).

The dielectric liner 114, the conductive fill material 148, and the first interconnect liner 142 constitute the interconnect structure 112. The conductive fill material 148 may comprise a right-cylindrical shape, an hourglass shape, a square shape, a rectangular shape, etc. The conductive fill material 148 may exhibit the lowest electrical resistivity of the materials of the interconnect structure 112, such as having an electrical resistivity of from about 5.0 E-4 μΩ·cm to about 6.0 E-4 μΩ·cm. The interconnect structure 112 may be electrically coupled to additional features (e.g., conductive features) of the microelectronic device structure 100. For example, conductive features positioned adjacent to (e.g., over) the interconnect structure 112 may be electrically coupled to the interconnect structure 112 and the contact structure 128a.

As described below, other embodiments of the microelectronic device structures 100′, 100″, 100′″ are similar to the microelectronic device structure 100 previously described with reference to FIGS. 2A-2E. The other embodiments of the microelectronic device structures 100′, 100″, 100′″ may be formed by processes similar to those previously described with reference to FIGS. 2A-2E. Unless otherwise specified, the material types, material thicknesses, etc., of the microelectronic device structures 100′, 100″, 100′″ are as described above for FIGS. 2A-2E. In addition, advantages of the microelectronic device structures 100′, 100″, 100′″ and of processes of forming the microelectronic device structures 100′, 100″, 100′″ are similar to those of the microelectronic device structure 100.

Referring to FIG. 2-1A, a contact structure 128a similar to the contact structure 128a of FIG. 2A is depicted where the dielectric liner 114 may have a first thickness, W₁, a second thickness, W₂, and a third thickness, W₃. W₃ may be substantially equivalent to the CD of the interconnect openings 116. One or more different formation acts are subsequently conducted, as shown in FIGS. 2-1B to 2-1E, to form a microelectronic device structure 100′. The microelectronic device structure 100′ differs from the microelectronic device structure 100 in the depth at which the second interconnect opening 138 is formed. The increased depth to which the second interconnect opening 138 is formed enables the conductive fill material 148 of the microelectronic device structure 100′ to be in direct contact with the conductive contact material 134 while the microelectronic device structure 100 includes the conductive fill material 148 in direct contact with the conductive barrier material 132.

Referring to FIG. 2-1B, the first material removal act may selectively remove a bottom portion of the dielectric liner 114, a portion of the underlying conductive barrier material 132, a portion of the underlying metal nitride material 136, and optionally, a portion of the conductive contact material 134 to form a second interconnect opening 138. The second interconnect opening 138 has a depth 150, which is deeper than the depth 140 described in relation to FIG. 2B. The bottom portion of the dielectric liner 114 and underlying portions of the conductive barrier material 132, the metal nitride material 136, and optionally, the conductive contact material 134 are removed while other portions of the dielectric liner 114, the conductive barrier material 132, and the metal nitride material 136 remain. The second interconnect opening 138 may, therefore, terminate at an upper surface of the conductive contact material 134. The depth 150 may be measured from an upper surface of the bottom portion of the dielectric liner 114 to the upper surface of the conductive contact material 134 and includes the thicknesses (e.g., vertically) of the bottom portion of the dielectric liner 114, the underlying conductive barrier material 132, and the underlying metal nitride material 136.

The first material removal act may be an etch process, such as a dry etch or a wet etch process as described above for FIG. 2B. The etch process may remove the desired portions of the dielectric liner 114, the conductive barrier material 132, and the metal nitride material 136. For example, the wet etch process may include etchants, such as a hydrofluorocarbon etching gas selected from the group consisting of 1,1,1,3,3,3-hexafluoropropane (C₃H₂F₆), 1,1,2,2,3,3-hexafluoropropane (iso-C₃H₂F₆), 1,1,1,2,3,3,3-heptafluoropropane (C₃HF₇), and 1,1,1,2,2,3,3-heptafluoropropane (iso-C₃HF₇), a mixture of ammonium hydroxide (NH₄OH) and water (e.g., deionized), and combinations thereof.

The first material removal act may optionally include an over-etch of the conductive contact material 134 to ensure good contact between the conductive contact material 134 and the subsequently formed conductive fill material 148 (see FIG. 2-1E). For example, from about 7 nanometers to about 10 nanometers of the conductive contact material 134 may be removed. In other embodiments, more than about 10 nanometers of material may be removed for over-etch.

Referring to FIG. 2-1C, a first interconnect liner 142 may be formed in the second interconnect opening 138. The first interconnect liner 142 may comprise a metal nitride material deposited along the sidewalls of the dielectric liner 114, the conductive barrier material 132, and the metal nitride material 136, and over the exposed surface of the conductive contact material 134. The first interconnect liner 142 may be formed by one or more conformal deposition techniques, such as one or more of an ALD or CVD process.

Referring to FIG. 2-1D, a second material removal act is conducted and selectively removes a bottom portion 151 of the first interconnect liner 142 to expose an upper surface 152 of the conductive contact material 134. The second material removal act may, optionally, form a native oxide 154 (e.g., contact interface), without substantially removing the first interconnect liner 142 on the sidewalls of the dielectric liner 114, the conductive barrier material 132, and the metal nitride material 136. An additional portion of the conductive contact material 134 may optionally be removed due to over-etch to ensure good contact between the conductive contact material 134 and the conductive fill material 148 (FIG. 2-1E). Removing the bottom portion 151 may eliminate the first interconnect liner 142 from the current flow path, preventing or reducing electrically impeding the flow of electrical current from the conductive fill material 148 of the interconnect structure 112 to the contact materials 130 of the contact structure 128a.

The first interconnect liner 142 remaining on the sidewalls of the dielectric liner 114, the conductive barrier material 132, the metal nitride material 136, and the conductive contact material 134 exhibits substantially the same thickness (e.g., a uniform lateral thickness). In other words, portions of the first interconnect liner 142 distal to and proximal to the contact materials 130 have substantially the same thicknesses.

Referring to FIG. 2-1E, the conductive fill material 148 is formed in the second interconnect opening 138, directly adjacent to the first interconnect liner 142, the conductive barrier material 132, the metal nitride material 136, and the conductive contact material 134. The conductive fill material 148 directly contacts the first interconnect liner 142, the conductive barrier material 132, the metal nitride material 136, and the conductive contact material 134. In some embodiments, the conductive fill material 148 comprises tungsten. By removing the bottom portion 151 of the first interconnect liner 142 to expose the upper surface 152 of the conductive contact material 134, the conductive fill material 148, which exhibits a relatively lower electrical resistivity than the first interconnect liner 142, may be in direct contact with the conductive contact material 134, which exhibits a relatively lower electrical resistivity than the first interconnect liner 142.

Referring to FIG. 2-2A, a contact structure 128a similar to the contact structure 128a of FIG. 2A is depicted, where a dielectric liner 114 may have a first thickness, W₁, a second thickness, W₂, and a third thickness, W₃. W₃ may be substantially equivalent to the CD of the first interconnect openings 116. One or more different formation acts are subsequently conducted, as shown in FIGS. 2-2B and 2-2C, to form a microelectronic device structure 100″, which differs from the microelectronic device structures 100. The microelectronic device structure 100″ differs from the microelectronic device structure 100 in that a conductive fill material 148 (FIG. 2-2C) exhibits different widths (e.g., diameters) along its depth. An upper portion of the conductive fill material 148 may be wider than a lower portion of the conductive fill material 148.

Referring to FIG. 2-2A, a first interconnect liner 142 may be formed (e.g., deposited) along the sidewalls and upper surface of the dielectric liner 114 defining a first interconnect opening 116. The first interconnect liner 142 may be formed of one or more conformal deposition techniques, such as one or more of an ALD or CVD process to substantially cover the sidewalls of the dielectric liner 114 and the upper surface of the dielectric liner 114, prior to conducting any additional material removal processes.

A first material removal process is conducted that selectively removes a horizontally oriented portion of the first interconnect liner 142 on the upper surface of the dielectric liner 114 and an underlying portion of the dielectric liner 114 to form a second interconnect opening 138 extending a depth 140. Removing the horizontally oriented portion of the first interconnect liner 142 may eliminate the first interconnect liner 142 from the current flow path, preventing or reducing electrically impeding the flow of electrical current from the conductive fill material 148 of the interconnect structure 112 to the contact materials 130 of the contact structure 128a. The second interconnect opening 138 exposes an upper surface of the conductive barrier material 132. The first material removal process does not substantially remove the first interconnect liner 142 on the sidewalls of the dielectric liner 114 and does not substantially remove the conductive barrier material 132. The first material removal process may include an etch process, such as a dry etch process, that “punches through” the horizontally oriented portions of the first interconnect liner 142 and the dielectric liner 114. Alternatively, the first material removal process may comprise an anisotropic wet etch process.

Referring to FIG. 2-2B, the first material removal process may form the second interconnect opening 138, which may further facilitate forming an additional portion of the first interconnect liner 142 exhibiting a reduced thickness within the second interconnect opening 138. The reduced thickness of the first interconnect liner 142 in the lower portion of the second interconnect opening 138 may occur at a step 156 starting just above the depth 140. Because the first material removal process occurs after forming the first interconnect liner 142, the upper surface 144 of the conductive barrier material 132 is exposed, with the first interconnect liner 142 remaining on the sidewalls of the dielectric liner 114.

Referring to FIG. 2-2C, a second interconnect liner 158 may be formed along the sidewalls of the dielectric liner 114, conductive barrier material 132, and metal nitride material 136 and on the upper surface 144 of the conductive barrier material 132. The second interconnect liner 158 and the first interconnect liner 142, in combination, form a substantially continuous interconnect liner on sidewalls of materials defining the second interconnect opening 138. The second interconnect liner 158 may also function as a seed material to facilitate growth of a conductive fill material 148 within the second interconnect opening 138, forming the microelectronic device structure 100″. The second interconnect liner 158 may be used in any of the embodiments disclosed herein that incorporate the second interconnect liner 158. The second interconnect liner 158 may be formed by one or more conformal deposition techniques, such as one or more of an ALD or CVD process. The second interconnect liner 158 may be formed of the same material as the first interconnect liner 142 or may be formed of a different material than the first interconnect liner 142.

The formation of the second interconnect liner 158 in the second interconnect opening 138 results in a change in width (e.g., diameter) of the conductive fill material 148 proximal to the contact materials 130 compared to distal to the contact materials 130. The change in width is indicated by the step 156 present at a transition between upper and lower portions of the second interconnect opening 138. While the transition between the upper and lower portions is illustrated as a step, the transition may comprise a continuous, or curved, tapering from an upper portion to a lower portion. The substantially continuous interconnect liner including the second interconnect liner 158 and the first interconnect liner 142 is relatively thinner proximal to the conductive barrier material 132 and relatively thicker distal to the conductive barrier material 132. In other words, the interconnect liner material may have non-uniform thicknesses above and below the step 156.

A conductive fill material 148 may be formed in a remaining volume of the second interconnect opening 138, directly adjacent to the first interconnect liner 142 and the second interconnect liner 158. In some embodiments, the conductive fill material 148 comprises tungsten. The interconnect structure 112, therefore, includes the conductive fill material 148, the dielectric liner 114, the first interconnect liner 142, and the second interconnect liner 158, with the conductive fill material 148 distal to the contact materials 130 being relatively wider than the conductive fill material 148 proximal to the contact materials 130. The conductive fill material 148 may, therefore, exhibit different widths along its height due to the step 156. With the second interconnect liner 158 being directly adjacent to the conductive barrier material 132 instead of the dielectric liner 114 being directly adjacent, electrical resistivity of the microelectronic device structure 100″ is increased relative to a conventional conductive contact structure (i.e., contact structure that is not formed according to the methods described herein).

Without being bound by theory, it is believed that the presence of the step 156 decreases an amount (e.g., diameter) of the second interconnect liner 158 that is in direct contact with the contact materials 130 (e.g., the conductive barrier material 132) of the contact structure 128a while maintaining the amount of conductive fill material 148 present in the interconnect structure 112. Because the volume of interconnect liner proximal to the contact structure 128a is reduced while maintaining the volume of fill material 148, an overall electrical resistivity within the contact structure 128a may be reduced.

Referring to FIG. 2-3A, a contact structure 128a similar to the contact structure 128a of FIG. 2A is depicted where the dielectric liner 114 may have a first thickness, W₁, a second thickness, W₂, and a third thickness, W₃. W₃ may be substantially equivalent to the CD of the first interconnect openings 116. One or more different formation acts are subsequently conducted, as shown in FIGS. 2-3B and 2-3C, to form a microelectronic device structure 100′″ that differs from the microelectronic device structures 100′, 100″ in that a conductive fill material 148 (FIG. 2-3C) exhibits different widths along its height and extends through the conductive barrier material 132 and into the conductive contact material 134.

A first interconnect liner 142 may be formed (e.g., deposited) along the sidewalls and upper surface of the dielectric liner 114, defining a first interconnect opening 116. The first interconnect liner 142 may be formed of one or more conformal deposition techniques, such as one or more of an ALD or CVD process to substantially cover the sidewalls of the dielectric liner 114 and the upper surface of the dielectric liner 114, prior to conducting any additional material removal processes.

A first material removal process may be conducted that selectively removes (e.g., selectively etches) a horizontally oriented portion of the first interconnect liner 142 along with an underlying portion of the dielectric liner 114, the conductive barrier material 132, and the metal nitride material 136, to form a second interconnect opening 138 extending a depth 150. The depth 150 is greater than the depth 140 of FIGS. 2B and 2-2B. Removing the horizontally oriented portion of the first interconnect liner 142 may improve the direct path of current flow. This first material removal process occurs without substantially removing vertically oriented portions of the first interconnect liner 142, the dielectric liner 114, the conductive barrier material 132, and the metal nitride material 136. The first material removal process also occurs without substantially removing the conductive contact material 134. The first material removal process may include an etch process, such as a dry etch process, that “punches through” both the first interconnect liner 142 and the dielectric liner 114. Alternatively, the first material removal process may comprise an anisotropic wet etch process to selectively etch the materials intervening between the conductive contact material 134 and a bottom portion of the second interconnect opening 138 (i.e., the first interconnect liner 142, the dielectric liner 114, the conductive barrier material 132, and the metal nitride material 136). Because the first material removal process occurs after forming the first interconnect liner 142, the upper surface 152 of the conductive barrier material 132 is exposed.

Referring to FIG. 2-3B, the first material removal process may form the second interconnect opening 138, which may facilitate the formation of the step 156 within the second interconnect opening 138. The step 156 may be formed relative to the sidewalls of the first interconnect liner 142, the sidewalls of the dielectric liner 114, the sidewalls of the conductive barrier material 132, and the sidewalls of the metal nitride material 136, just above the depth 150. The step 156 may further facilitate forming an additional portion of the interconnect liner exhibiting a reduced thickness within the second interconnect opening 138. The reduced thickness of the second interconnect liner 158 in the lower portion of the second interconnect opening 138 may occur starting just above the depth 150.

Referring to FIG. 2-3C, a second interconnect liner 158 comprising a conductive material may be formed along the sidewalls of the dielectric liner 114 and the conductive barrier material 132 and the upper surface of the conductive contact material 134. The second interconnect liner 158 may be formed by one or more conformal deposition techniques, such as one or more of an ALD or CVD process. The second interconnect liner 158 may be formed of the same material as the first interconnect liner 142 or may be formed of a different material than the first interconnect liner 142. The second interconnect liner 158 and the first interconnect liner 142, in combination, form a substantially continuous interconnect liner on sidewalls of materials defining the second interconnect opening 138.

The formation of the second interconnect liner 158 in the second interconnect opening 138 results in a change in width (e.g., diameter) of the conductive fill material 148 proximal to the contact materials 130 compared to the width distal to the contact materials 130. The change in width is indicated by the step 156 present at a transition between upper and lower portions of the second interconnect opening 138. While the transition between the upper and lower portions is illustrated as a step, the transition may comprise a continuous, or curved, tapering from an upper portion to a lower portion. The substantially continuous interconnect liner including the second interconnect liner 158 and the first interconnect liner 142 is relatively thinner proximal to the conductive barrier material 132 and relatively thicker distal to the conductive barrier material 132. In other words, the interconnect liner material may have non-uniform thicknesses above and below the step 156.

A conductive fill material 148 may be formed in a remaining volume of the second interconnect opening 138, directly adjacent to the first interconnect liner 142 and the second interconnect liner 158, forming the depicted portion of the microelectronic device structure 100′″. The second interconnect liner 158 may function as a seed material to facilitate growth of the conductive fill material 148 within the second interconnect opening 138. In some embodiments, the conductive fill material 148 comprises tungsten. The interconnect structure 112, therefore, includes the conductive fill material 148, the dielectric liner 114, the first interconnect liner 142, and the second interconnect liner 158, with the conductive fill material 148 distal to the contact materials 130 being relatively wider than the conductive fill material 148 proximal to the contact materials 130. The conductive fill material 148 may, therefore, exhibit different widths along its height due to the step 156. With the second interconnect liner 158 being directly adjacent to the conductive barrier material 132 instead of the dielectric liner 114 being directly adjacent, electrical resistivity of the microelectronic device structure 100′″ is increased relative to a conventional conductive contact structure (i.e., contact structure that is not formed according to the methods described herein).

Without being bound by theory, it is believed that the presence of the step 156 decreases an amount (e.g., diameter) of the second interconnect liner 158 that is in direct contact with the contact materials 130 (e.g., the conductive barrier material 132) of the contact structure 128a while maintaining the amount of conductive fill material 148 present in the interconnect structure 112. Because the volume of interconnect liner proximal to the contact structure 128a is reduced while maintaining the volume of fill material 148, an overall electrical resistivity within the contact structure 128a may be reduced.

FIGS. 3A through 3E, FIGS. 3-1A through 3-1E, FIGS. 3-2A through 3-2C, and FIGS. 3-3A through 3-3C are partial, cross-sectional views of embodiments of contact structures 128b and interconnect structures 112 depicted at various stages during the process of forming embodiments of the microelectronic device structure 101, 101′, 101″, 101′″. FIGS. 3A through 3E, FIGS. 3-1A through 3-1E, FIGS. 3-2A through 3-2C, and FIGS. 3-3A through 3-3C are enlargements of the portion of the microelectronic device structure 101, 101′, 101″, 101′″ indicated by the dashed box in FIG. 1C. FIGS. 3A through 3D, FIGS. 3-1A through 3-1D, FIGS. 3-2A through 3-2B, and FIGS. 3-3A through 3-3B illustrate earlier process acts and FIGS. 3E, 3-1E, 3-2C, and 3-3C illustrate the microelectronic device structure 101, 101′, 101″, 101′″ including the contact structures 128b and the interconnect structures 112 in relation to the source material 126. The contact materials 130 of the contact structure 128b, including the conductive barrier material 132, the conductive contact material 134, and the metal nitride material 136, are shown in relation to the dielectric liner 114, the conductive fill material 148, and the first interconnect liner 142 of the interconnect structures 112. Only those process acts and materials that are different than those previously described are described in detail below.

As described below, embodiments of the microelectronic device structures 101, 101′, 101″, 101′″ are similar to the microelectronic device structure 100 previously described with reference to FIGS. 2A-2E. The embodiments of the microelectronic device structures 101, 101′, 101″, 101′″ may be formed by processes similar to those previously described with reference to FIGS. 2A-2E. Unless otherwise specified, the material types, material thicknesses, etc., of the microelectronic device structures 101, 101′, 101″, 101′″ are as described above for FIGS. 2A-2E. In addition, advantages of the microelectronic device structures 101, 101′, 101″, 101′″ and of processes of forming the microelectronic device structures 101, 101′, 101″, 101′″ are similar to those of the microelectronic device structure 100, 100′, 100″, 100′″.

Referring to FIG. 3A, the dielectric liner 114 is formed (e.g., conformally formed) in the first interconnect opening 116 and has a first thickness, W₄, a second thickness, W₅, and a third thickness, W₆, where W₆ may be substantially equivalent to the CD of the first interconnect openings 116. W₄ and W₅ may be substantially equal to one another and W₆ may be greater than W₄ or W₅. The dielectric liner 114 is formed on opposite sidewalls of the tiers 118 and source material 126 through which the first interconnect opening 116 extends and partially fills the first interconnect opening 116. As shown in FIG. 3A, a portion of the source material 126 vertically intervenes between the dielectric liner 114 and the conductive barrier material 132. Therefore, one or more process acts in forming and/or metalizing the contact structure 128b may be different than one or more process acts used in forming and/or metalizing the contact structure 128a.

Referring to FIG. 3B, a first material removal act is conducted and selectively removes a bottom portion of the dielectric liner 114 along with a portion of the source material 126 to create a second interconnect opening 138 and obtain a depth 140. The first material removal act removes horizontally oriented portions of the dielectric liner 114 and the source material 126, exposing an upper surface of the conductive barrier material 132. The first material removal process extends the depth of the first interconnect opening 116 and forms the second interconnect opening 138, without substantially removing the dielectric liner 114, the source material 126, and the conductive barrier material 132. The second interconnect opening 138 terminates at the upper surface of the conductive barrier material 132. The depth 140 may be an additional depth beyond the initial depth of the interconnect opening 116, where the additional depth is substantially equivalent to the thickness of the dielectric liner 114 and the source material 126.

The first material removal act includes an etch process, such as a dry etch process, that removes the portion of the dielectric liner 114 and the source material 126. The first material removal act may, for example, be an RIE process. Alternatively, the first material removal act may be an in situ, anisotropic wet etch process.

Referring to FIG. 3C, a first interconnect liner 142 may be formed on sidewalls of the dielectric liner 114 and the source material 126, and over the exposed surface of the conductive barrier material 132. The first interconnect liner 142 may comprise a conductive material and may be formed by one or more conformal deposition techniques, such as one or more of an ALD or CVD process. Portions of the first interconnect liner 142 that are outside or above the second interconnect openings 138 may be removed through a chemical or mechanical material removal process, such as a CMP planarization process. As the first interconnect liner 142 is formed, exposed portions of the source material 126 may be converted into a conductive coating material 160 by the reaction of reactants and/or precursors of the first interconnect liner 142 with the source material 126. The conductive coating material 160 may comprise any suitable metal-containing composition, such as a metal silicide. In some embodiments, the conductive coating material 160 comprises titanium silicide.

Referring to FIG. 3D, a second material removal process is conducted to selectively remove a bottom portion 141 of the first interconnect liner 142. Removing the bottom portion 141 of the first interconnect liner 142 exposes an upper surface 144 of the conductive barrier material 132, if present, and optionally forms a native oxide 146, without substantially removing the first interconnect liner 142 from the sidewalls of the dielectric liner 114 and without substantially removing the conductive barrier material 132. Removing the bottom portion 141 of the first interconnect liner 142 may improve the direct path of current flow from the conductive fill material 148 of the interconnect structure 112 to the contact materials 130 of the contact structure 128b. The native oxide 146 may be formed depending on environmental conditions under which the second material removal process occurs. The second material removal act may include an etch process, such as a wet etch process, that selectively etches the bottom portion 141 of the first interconnect liner 142 relative to the contact materials 130 of the contact structure 128b. The first interconnect liner 142 has substantially the same thickness (e.g., uniform lateral thickness) along the sidewalls of the dielectric liner 114 and the conductive coating material 160. In other words, portions of the first interconnect liner 142 proximal to and distal to the conductive barrier material 132 exhibit substantially the same thickness.

Referring to FIG. 3E, a conductive fill material 148 is formed in the second interconnect opening 138 directly adjacent to the conductive barrier material 132 or to the native oxide 146, if present. The conductive fill material 148 may also be directly adjacent to the first interconnect liner 142 and the conductive coating material 160. Therefore, the conductive fill material 148 may be in direct contact with the conductive barrier material 132, the first interconnect liner 142, the conductive coating material 160, and, optionally, the native oxide 146. The conductive fill material 148 substantially fills the remaining volume of the second interconnect opening 138. The conductive fill material 148 may, for example, be the same material composition, such as tungsten, as the conductive contact material 134 or may be a different material composition. The conductive fill material 148 may exhibit substantially the same electrical resistivity or conductivity as the conductive contact material 134. Alternatively, the conductive fill material 148 may exhibit a different electrical resistivity than the conductive contact material 134. Similar to embodiments described above, the conductive fill material 148 together with the first interconnect liner 142 and the dielectric liner 114 constitute the interconnect structure 112. If the native oxide 146 is present, the conductive fill material 148 may be in direct contact with the native oxide 146 and the native oxide 146 may be in direct contact with the conductive barrier material 132.

Referring to FIG. 3-1A, a contact structure 128b similar to the contact structure 128b of FIG. 3A is depicted. Although the contact structure 128b of FIG. 3-1A is at a similar stage to the contact structure of FIG. 3A, one or more different process acts may subsequently be conducted to form a microelectronic device structure 101′.

Referring to FIG. 3-1B, a first material removal process may be conducted to selectively remove a bottom portion of the dielectric liner 114, a portion of the source material 126, a portion of the conductive barrier material 132, a portion of the metal nitride material 136, and a portion of the conductive contact material 134 to create a second interconnect opening 138. The second interconnect opening 138 may extend to a depth 150. The selective removal may be achieved without substantially removing other portions of the dielectric liner 114, the source material 126, the conductive barrier material 132, and the metal nitride material 136. The first material removal process may include an etch process, such as a dry etch or an anisotropic, selective, wet etch process.

Referring to FIG. 3-1C, a first interconnect liner 142 may be formed on sidewalls of the dielectric liner 114, the source material 126, the conductive barrier material 132, and the metal nitride material 136 and on an exposed horizontal surface of the conductive contact material 134. The first interconnect liner 142 may comprise a conductive material and may be formed by one or more conformal deposition techniques, such as one or more of an ALD or CVD process. Portions of the first interconnect liner 142 that are outside or above the second interconnect openings 138 may be removed through a chemical or mechanical material removal process, such as a CMP planarization process. As the first interconnect liner 142 is formed, exposed portions of the source material 126 may be converted into a conductive coating material 160 by the reaction of reactants and/or precursors of the first interconnect liner 142 with the source material 126. The conductive coating material 160 may comprise any suitable metal-containing composition, such as a metal silicide. In some embodiments, the conductive coating material 160 comprises titanium silicide.

Referring to FIG. 3-1D, a second material removal act is conducted to selectively remove a bottom portion 151 of the first interconnect liner 142. Removing the bottom portion 151 exposes an upper surface 152 of the conductive contact material 134, without substantially removing the first interconnect liner 142 from the sidewalls of the dielectric liner 114, the conductive coating material 160, and the conductive barrier material 132. Removing the bottom portion 151 of the first interconnect liner 142 may improve the direct path of current flow from the conductive fill material 148 of the interconnect structure 112 to the contact materials 130 of the contact structure 128b. A native oxide 154 may optionally be formed on the upper surface 152. The first interconnect liner 142 has substantially the same thickness (e.g., a uniform lateral thickness) on the sidewalls of the dielectric liner 114, the conductive coating material 160, and the conductive barrier material 132. In other words, portions of the first interconnect liner 142 proximal to and distal to the contact materials 130 may exhibit the same thickness.

Referring to FIG. 3-1E, a conductive fill material 148 is formed in the second interconnect opening 138, directly adjacent to the first interconnect liner 142, the conductive coating material 160, the conductive barrier material 132, the metal nitride material 136, and the conductive contact material 134, forming the microelectronic device structure 101′. The conductive fill material 148 may exhibit substantially the same electrical resistivity or conductivity as the conductive contact material 134. Alternatively, the conductive fill material 148 may exhibit a different electrical resistivity than the conductive contact material 134. The conductive fill material 148 may be in direct contact with the first interconnect liner 142, the conductive coating material 160, the conductive barrier material 132, the metal nitride material 136, and the conductive contact material 134. If the native oxide 154 is present, the conductive fill material 148 may be in direct contact with the native oxide 154 and the native oxide 154 may be in direct contact with the conductive contact material 134. Upper portions and lower portions of the first interconnect liner 142 exhibit a substantially uniform thickness and upper portions and lower portions of the conductive fill material 148 exhibit a substantially uniform diameter.

Referring to FIG. 3-2A, a contact structure 128b similar to the contact structure 128b of FIG. 3A. The dielectric liner 114 is formed on opposite sidewalls of the tiers 118 and source material 126 through which the first interconnect opening 116 extends and partially fills the first interconnect opening 116. As shown in FIG. 3-2A, the contact structure 128b includes a portion of the source material 126 vertically intervening between the dielectric liner 114 and the conductive barrier material 132. Although the contact structure 128b of FIG. 3-2A is at a similar stage to the contact structure of FIG. 3A, one or more different process acts may subsequently be conducted to form a microelectronic device structure 101″.

Referring to FIG. 3-2B, a first interconnect liner 142 may be formed on sidewalls of the dielectric liner 114 and may comprise a conductive material. The first interconnect liner 142 may be formed by one or more conformal deposition techniques, such as one or more of an ALD or CVD process. Portions of the first interconnect liner 142 that are outside or above the second interconnect openings 138 may be removed through a chemical or mechanical material removal process, such as a CMP planarization process.

Referring to FIG. 3-2C, a first material removal process is conducted that selectively removes portions of the first interconnect liner 142, the dielectric liner 114, and the source material 126, to create a second interconnect opening 138 that extends a depth 140. This first material removal process removes horizontally oriented portions of underlying materials without substantially removing other portions of the first interconnect liner 142, the dielectric liner 114, and the source material 126 and without substantially removing the conductive barrier material 132. Removing the horizontally oriented portion of the first interconnect liner 142 may improve the direct path of current flow from the conductive fill material 148 of the interconnect structure 112 to the contact materials 130 of the contact structure 128b. The second interconnect opening 138 terminates at an upper surface of the conductive barrier material 132. The depth 140 may be an additional depth beyond the initial depth of the interconnect opening 116, where the additional depth is substantially equivalent to the thickness of the dielectric liner 114, the source material 126, and the first interconnect liner 142. The first material removal act includes an etch process, such as a dry etch process or a wet etch process, that removes the portion of the dielectric liner 114 and the source material 126. The first material removal act may, for example, be an RIE process. Alternatively, the first material removal act may be an in situ, anisotropic wet etch process. The first material removal act may expose an upper surface of the conductive barrier material 132. The first material removal process may, optionally, convert a portion of the source material 126 to the conductive coating material 160.

The first material removal process may facilitate the formation of the step 156 within the second interconnect opening 138. The step 156 may be located at a transition in width between upper and lower portions of the second interconnect opening 138. Because the first material removal process may occur after forming the first interconnect liner 142, the upper portions of the second interconnect opening 138 may exhibit a relatively greater width than the lower portions of the second interconnect opening 138. The different widths may occur as previously described.

The second interconnect liner 158 may be formed along the sidewalls of the dielectric liner 114 and the source material 126. The second interconnect liner 158 may also function as a seed material to facilitate growth of the conductive fill material 148 within the second interconnect opening 138, forming the microelectronic device structure 101″. The second interconnect liner 158 may be formed by one or more conformal deposition techniques, such as one or more of an ALD or CVD. The second interconnect liner 158 may be formed of substantially the same material as the first interconnect liner 142 or of a different material. The second interconnect liner 158 in combination with the first interconnect liner 142 constitutes a substantially continuous interconnect liner that exhibits a greater thickness distal to the contact materials 130 and a lesser thickness proximal to the contact materials 130. In other words, the interconnect liner may have non-uniform thicknesses above and below the step 156.

A conductive fill material 148 may be formed directly adjacent to the second interconnect liner 158 and the first interconnect liner 142, extending substantially to the depth 140, forming the depicted portion of the microelectronic device structure 101″. In some embodiments, the conductive fill material 148 comprises tungsten. The fill material 148 may exhibit different widths along its height due to the step 156. The conductive fill material 148 exhibits a greater diameter distal to the contact materials 130 than proximal to the contact materials 130. Because the volume of interconnect liner in the contact structure 128b is reduced while maintaining the volume of fill material 148, an overall electrical resistivity within the contact structure 128b may be reduced.

Referring to FIG. 3-3A, a contact structure 128b similar to the contact structure 128b of FIG. 3A is depicted. As shown in FIG. 3-3A, the contact structure 128b includes a portion of the source material 126 vertically intervening between the dielectric liner 114 and the conductive barrier material 132. Although the contact structure 128b of FIG. 3-3A is at a similar stage to the contact structure of FIG. 3A, one or more different process acts may subsequently be conducted to form a microelectronic device structure 101′″.

Referring to FIG. 3-3B, a first interconnect liner 142 may be formed on sidewalls of the dielectric liner 114 and may comprise a conductive material. The first interconnect liner 142 may be formed by one or more conformal deposition techniques, such as one or more of an ALD or CVD process. Portions of the first interconnect liner 142 that are outside or above the second interconnect openings 138 may be removed through a chemical or mechanical material removal process, such as a CMP planarization process.

Referring to FIG. 3-3C, a first material removal process is conducted that selectively removes portions of the first interconnect liner 142, the dielectric liner 114, the source material 126, and the conductive barrier material 132 to create a second interconnect opening 138 that extends a depth 150. The second interconnect opening 138 terminates at an upper surface of the conductive contact material 134. This first material removal process removes horizontally oriented portions of the materials without substantially removing other portions of the first interconnect liner 142, the dielectric liner 114, the source material 126, and the conductive barrier material 132. Removing the horizontally oriented portion of the first interconnect liner 142 may improve the direct path of current flow from the conductive fill material 148 of the interconnect structure 112 to the contact materials 130 of the contact structure 128b. The first material removal process may facilitate the formation of the step 156 within the second interconnect opening 138. The step 156 may be located at a transition in width between upper and lower portions of the second interconnect opening 138. Because the first material removal process occurs after forming the first interconnect liner 142, the upper portions of the second interconnect opening 138 may exhibit a relatively greater width than the lower portions of the second interconnect opening 138. The different widths may occur as previously described. The first material removal process may, optionally, convert a portion of the source material 126 to the conductive coating material 160.

The depth 150 may be an additional depth beyond the initial depth of the interconnect opening 116, where the additional depth is substantially equivalent to the thickness of the dielectric liner 114, the source material 126, the first interconnect liner 142, the conductive barrier material 132, and a portion of the conductive contact material 134. The first material removal act includes an etch process, such as a dry etch process or a wet etch process, that removes the desired portions of materials. The first material removal act may, for example, be an RIE process. Alternatively, the first material removal act may be an in situ, anisotropic wet etch process. The first material removal act may expose the upper surface of the conductive contact material 134.

The second interconnect liner 158 may be formed along the sidewalls of the dielectric liner 114, the source material 126, the conductive barrier material 132 and the upper surface of the conductive contact material 134. The second interconnect liner 158 may function as a seed material to facilitate growth of the conductive fill material 148 within the second interconnect opening 138, forming the microelectronic device structure 101′″. The second interconnect liner 158 may be formed by one or more conformal deposition techniques, such as one or more of an ALD or CVD. The second interconnect liner 158 may be formed of substantially the same material as the first interconnect liner 142 or of a different material. The second interconnect liner 158 results in a combined interconnect liner (e.g., first interconnect liner 142 and second interconnect liner 158) that is lesser in thickness proximal to the contact materials 130 and greater in thickness distal to the contact materials 130. In other words, the interconnect liner may have non-uniform thicknesses above and below the step 156.

Referring to FIG. 3-3D, the conductive fill material 148 may be formed directly adjacent to the second interconnect liner 158 and the first interconnect liner 142, extending substantially to the depth 150, forming the depicted portion of the microelectronic device structure 101′″. In some embodiments, the conductive fill material 148 comprises tungsten. The fill material 148 may exhibit different widths along its height due to the step 156. The conductive fill material 148 exhibits a greater diameter distal to the contact materials 130 than proximal to the contact materials 130. Because the volume of interconnect liner in the contact structure 128b is reduced while maintaining the volume of fill material 148, an overall electrical resistivity within the contact structure 128b may be reduced.

Accordingly, a microelectronic device is disclosed and comprises a source material adjacent to tiers of alternating conductive materials and dielectric materials. Interconnect structures extend through the tiers and into the source material. One or more of the interconnect structures comprises a dielectric liner adjacent to the tiers and the source material, a first interconnect liner adjacent to the dielectric liner, and a conductive fill material extending between opposing surfaces of the first interconnect liner. Contact structures within the source material are electrically coupled to the interconnect structures and one or more of the contact structures comprise a conductive barrier material adjacent to the interconnect structures, a metal nitride material adjacent to the conductive barrier material, and a conductive contact material adjacent to the metal nitride material. The conductive fill material of the interconnect structures is in electrical contact with the conductive barrier material of the contact structures.

Accordingly, another microelectronic device is disclosed and comprises interconnect structures extending vertically through tiers of alternating oxide materials and conductive materials adjacent to a source material. The interconnect structures comprise a dielectric liner surrounding an interconnect liner and a conductive fill material. Contact structures are adjacent to and electrically coupled to the interconnect structures. The contact structures comprise one or more contact materials in direct contact with the conductive fill material of the interconnect structures. A relatively higher electrical resistivity material of the one or more contact materials is in direct contact with the conductive fill material of the interconnect structures.

A method of forming a microelectronic device is disclosed and comprises forming contact structures comprising one or more contact materials in a source material. Tiers of alternating oxide materials and conductive materials are formed adjacent to the source material and interconnect openings are formed through the tiers of alternating oxide materials and conductive materials. A dielectric liner and an interconnect liner are formed within the interconnect openings, and a portion of the interconnect liner overlying the one or more contact materials of the contact structures is removed. An interconnect fill material is formed within the interconnect openings, and the interconnect fill material directly contacts the one or more contact materials. The dielectric liner and the interconnect liner surround the interconnect fill material.

FIG. 4 is a diagrammatic cross-sectional side view of a multi-deck assembly of microelectronic device 400, in accordance with embodiments of the disclosure. The multi-deck assembly of microelectronic device 400 may comprise a microelectronic device including a first one or more decks comprising a stack that is similar, if not identical to, stack 102 of the microelectronic device structures 100, 100′, 100″, 100′″, 101, 101′, 101″, 101′″. The first one or more decks may be formed in a similar manner to the stack 102 of any of the preceding microelectronic device structures 100, 100′, 100″, 100′″, 101, 101′, 101″, 101′″ described above relative to FIGS. 1A to 3-3D. In some embodiments, the first one or more decks of FIG. 4 may differ from the stack 102 in at least one material property or at least one structural feature. For example, the first one or more decks may differ from stack 102 by including an array region 104a and another array region 104b laterally disposed on either side of an interconnect structure 112, such that the interconnect structure 112 is laterally intervening between the array regions 104a, 104b.

The first one or more decks may be electrically and/or physically connected (e.g., at least via dashed arrow line connections 162) to one or more additional decks (e.g., second deck 164 and third deck 166). The second deck 164 and the third deck 166 may comprise components (e.g., tiers of alternating conductive and dielectric materials) that are similar to the components of the microelectronic device structure 100. The third deck 166 may be different from the first one or more decks and the second deck 164 at least by including control logic components and circuitry 168. The control logic components and circuitry 168 of the third deck 166 may be connected by way of one or more contact structures 128 to the interconnect structures 112 of the first one or more decks or of the second deck 164. For example, the third deck 166 may comprise a CMOS device that is connected to each memory deck of a 3D NAND memory device.

In some embodiments, the decks of the multi-deck assembly of microelectronic device 400 may be components of the same microelectronic device structure; while, in other embodiments, the decks may be separate components of separate microelectronic device structures. For example, the first one or more decks and the second deck 164 may be combined to comprise one microelectronic device structure; while, in other embodiments, the first one or more decks, such as the one or more stacks 102, are a component of the microelectronic device structure 100, the second deck 164 is a component of a second microelectronic device structure, and the third deck 166 is a component of a third microelectronic device structure.

In some embodiments, the third deck 166, including the CMOS device, may be formed prior to the second deck 164 and the first one or more decks. In this way, upon completing either the second deck 164 or the first one or more decks, an interconnect structure 112 is “dropped down” to or formed to connect the contact structure 128 and the interconnect structure 112 with a metal contact of the control logic circuitry of the third deck 166. The interconnect structures 112 and the contact structures 128 connecting the multi-deck assembly of microelectronic device 400 may be formed according to the methods discussed above relative to FIGS. 1A to 3-3D.

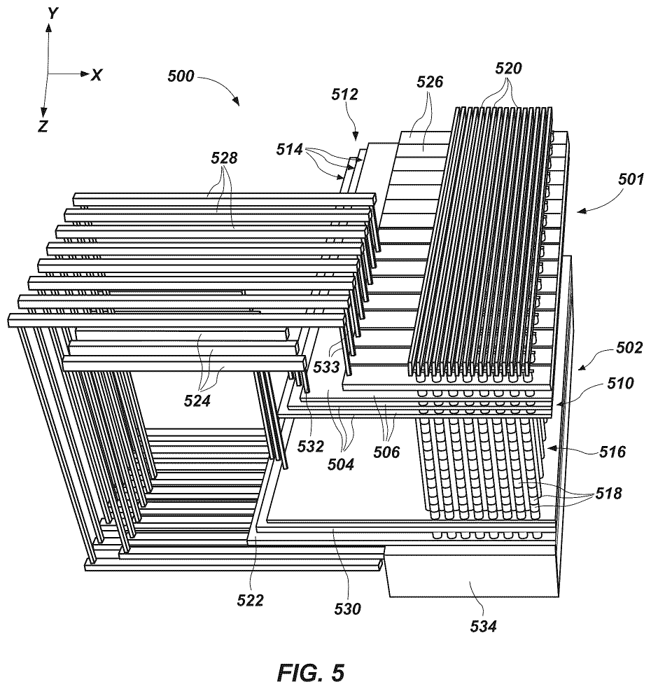

Referring to FIG. 5, microelectronic device structures 100, 100′, 100″, 100′″, 101, 101′, 101″, 101′″ of the disclosure may be included in microelectronic devices (e.g., memory devices) of the disclosure. For example, FIG. 5 illustrates a simplified, partial cutaway perspective view of a microelectronic device 500 (e.g., a memory device, such as a 3D NAND Flash memory device) including a microelectronic device structure 501 substantially similar to the microelectronic device structures 100, 100′, 100″, 100′″, 101, 101′, 101″, 101′″ at or following the processing stage previously described with reference to FIGS. 1A to 3-3D. For clarity and ease of understanding the drawings and associated description, some features (e.g., structures, materials) of the microelectronic device structures 100, 100′, 100″, 100′″, 101, 101′, 101″, 101′″ previously described herein are not shown in FIG. 5. However, it will be understood that any features of the microelectronic device structures 100, 100′, 100″, 100′″, 101, 101′, 101″, 101′″ at or preceding a processing stage previously described with reference to one or more of FIGS. 1A through 3-3D, may be included in a microelectronic device structure of microelectronic device 500 described herein with reference to FIG. 5.

As shown in FIG. 5, the microelectronic device 500 may include a deck structure 502 including a vertically alternating (e.g., in the Z-direction) sequence of conductive structures 504 and insulative structures 506 arranged in tiers 510 each including at least one of the conductive structures 504 vertically adjacent at least one of the insulative structures 506. The deck structure 502, the conductive structures 504, the insulative structures 506, and the tiers 510 may respectively correspond to the one or more stacks 102, the conductive structures (e.g., conductive materials 120), the insulative structures (e.g., dielectric materials 122), and the tiers 118 previously described with reference to FIGS. 1A to 3-3D. In addition, the microelectronic device 500 includes cell pillar structures 518 corresponding to the structures of the memory cell pillars 110 previously described with reference to FIGS. 1A to 3-3D, vertically extending through the deck structure 502. Intersections of the cell pillar structures 518 and the conductive structures 504 of the deck structure 502 form strings of memory cells 516 vertically extending through the deck structure 502. The conductive structures 504 may serve as local access line structures (e.g., local word line structures) for the strings of memory cells 516. Furthermore, the microelectronic device 500 may also include one or more staircase structures 512 having steps 514 defined by edges (e.g., horizontal ends in the X direction) of the tiers 510 of the deck structure 502. The steps 514 of the staircase structures 512 may serve as contact regions for the conductive structures 504 of the deck structure 502.

The microelectronic device 500 may further include at least one source structure 522, access line routing structures 524, first select gates 526 (e.g., upper select gates, drain select gates (SGDs)), select line routing structures 528, one or more second select gates 530 (e.g., lower select gates, source select gate (SGSs)), digit line structures 520, access line contact structures 532, and select line contact structures 533. Portions of the access line contact structures 532 or the select line contact structures 533 of the microelectronic device may correspond to the interconnect structures 112 and contact structures 128 previously described with reference to FIGS. 1A to 3-3D. The digit line structures 520 may be coupled to the cell pillar structures 518 by way of additional contact structures, plug structures, and pillar contact structures. For example, the digit line structures 520 may vertically overlie and physically contact the additional contact structures; the additional contact structures may vertically overlie and physically contact the plug structures; the plug structures may vertically overlie and physically contact the pillar contact structures; and the pillar contact structures may physically contact the cell pillar structures 518 (e.g., corresponding to the memory cell pillars 110 (FIG. 1A)). In addition, the access line contact structures 532 and the select line contact structures 533 may couple additional features of the microelectronic device 500 to one another as shown (e.g., the select line routing structures 528 to the first select gates 526, the access line routing structures 524 to the conductive structures 504 of the tiers 510 of the deck structure 502).

The microelectronic device 500 may also include a base structure 534 positioned vertically below the cell pillar structures 518 (and, hence, the strings of memory cells 516). The base structure 534 may include at least one control logic region including control logic devices configured to control various operations of other features (e.g., the strings of memory cells 516) of the microelectronic device 500. As a non-limiting example, the control logic region of the base structure 534 may further include one or more (e.g., each) of charge pumps (e.g., VCCP charge pumps, VNEGWL charge pumps, DVC2 charge pumps), delay-locked loop (DLL) circuitry (e.g., ring oscillators), V_{dd} regulators, drivers (e.g., string drivers), page buffers, decoders (e.g., local deck decoders, column decoders, row decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry, row repair circuitry), I/O devices (e.g., local I/O devices), memory test devices, MUX, error checking and correction (ECC) devices, self-refresh/wear leveling devices, and other chip/deck control circuitry. The control logic region of the base structure 534 may be coupled to the source structure 522, the access line routing structures 524, the select line routing structures 528, and the digit line structures 520. In some embodiments, the control logic region of the base structure 534 includes CMOS (complementary metal-oxide-semiconductor) circuitry. In such embodiments, the control logic region of the base structure 534 may be characterized as having a “CMOS under Array” (“CuA”) configuration. Although a CuA configuration is depicted, in other embodiments, the base structure 534 may be located above the digit line structures 520 and configured as a “CMOS over Array” (“CoA”) device.

Microelectronic device structures (e.g., the microelectronic device structures 100, 100′, 100″, 100′″, 101, 101′, 101″, 101′″ at or following the processing stage previously described with reference to FIGS. 1A to 3-3D) and microelectronic devices (e.g., the microelectronic device 500 (FIG. 5)) in accordance with embodiments of the disclosure may be used in embodiments of electronic systems of the disclosure.

The microelectronic device 500 according to embodiments of the disclosure may include, but is not limited to, a 3D microelectronic device, such as a 3D NAND Flash memory device, such as a multideck 3D NAND Flash memory device. The microelectronic device 500 formed according to embodiments of the disclosure may be used in any 3D microelectronic device where reduced or eliminated pillar misalignment is desired.

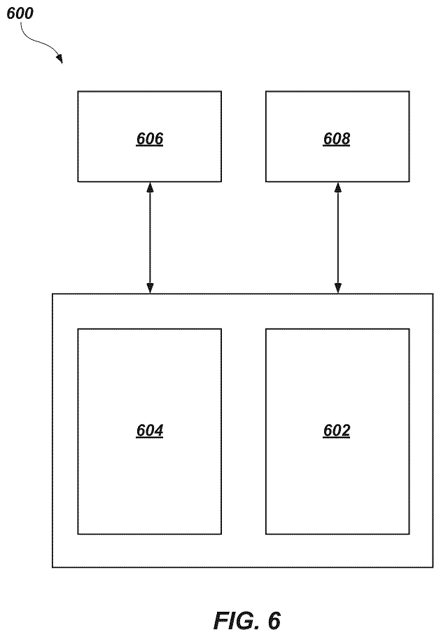

For example, FIG. 6 is a block diagram of a microelectronic system 600 implemented according to one or more embodiments described herein. The microelectronic system 600 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® or SURFACE® tablet, an electronic book, a navigation device, etc. The microelectronic system 600 includes at least one memory device 602, which includes one or more microelectronic device structures 100, 100′, 100″, 100′″, 101, 101′, 101″, 101′″ as previously described. The microelectronic system 600 may further include at least one processor 604, such as a microprocessor, to control the processing of system functions and requests in the microelectronic system 600. The processor 604 and other subcomponents of the microelectronic system 600 may include the memory cells. The processor 604 may, optionally, include one or more microelectronic device structures 100, 100′, 100″, 100′″, 101, 101′, 101″, 101′″ as previously described relative to FIGS. 1A to 3-3D.

Various other devices may be coupled to the processor 604 depending on the functions that the microelectronic system 600 performs. For example, an input device 606 may be coupled to the processor 604 for inputting information into the microelectronic system 600 by a user, such as, for example, a mouse or other pointing device, a button, a switch, a keyboard, a touchpad, a light pen, a digitizer and stylus, a touch screen, a voice recognition system, a microphone, a control panel, or a combination thereof. An output device 608 for outputting information (e.g., visual or audio output) to a user may also be coupled to the processor 604. The output device 608 may include an LCD display, an SED display, a CRT display, a DLP display, a plasma display, an OLED display, an LED display, a three-dimensional projection, an audio display, or a combination thereof. The output device 608 may also include a printer, an audio output jack, a speaker, etc. In some embodiments, the input device 606 and the output device 608 may comprise a single touchscreen device that can be used both to input information to the microelectronic system 600 and to output visual information to a user. The one or more input devices 606 and output devices 608 may communicate electrically with at least one of the memory device 602 and the processor 604. The at least one memory device 602 and processor 604 may also be used in a system on chip (SoC).

Accordingly, disclosed is a microelectronic system comprising an input device, an output device, a processor device operably coupled to the input device and the output device, and a memory device operably coupled to the processor device. The memory device may be made up of one or more decks including tiers of alternating oxide materials and conductive materials. The memory device may further include pillars extending vertically through the one or more decks and a cap material over the one or more decks. The cap material may include a different oxide material than the oxide materials of the tiers. The memory device may further include a plug laterally adjacent to the cap material and overlying the pillars, where the plug exhibits two or more different widths along a height thereof.

While certain illustrative embodiments have been described in connection with the figures, those of ordinary skill in the art will recognize and appreciate that embodiments encompassed by the disclosure are not limited to those embodiments explicitly shown and described herein. Rather, many additions, deletions, and modifications to the embodiments described herein may be made without departing from the scope of embodiments encompassed by the disclosure, such as those hereinafter claimed, including legal equivalents. In addition, features from one disclosed embodiment may be combined with features of another disclosed embodiment while still being encompassed within the scope of the disclosure.

What is claimed is:

1. A microelectronic device, comprising:
a source material adjacent to tiers of alternating conductive materials and dielectric materials;
interconnect structures extending through the tiers and into the source material, one or more of the interconnect structures comprising:
a dielectric liner adjacent to the tiers and the source material;
a first interconnect liner adjacent to the dielectric liner; and
a conductive fill material extending between opposing surfaces of the first interconnect liner; and
contact structures within the source material and electrically coupled to the interconnect structures, one or more of the contact structures comprising:
a conductive barrier material adjacent to the interconnect structures, a metal nitride material adjacent to the conductive barrier material, and a conductive contact material adjacent to the metal nitride material, the conductive fill material of the interconnect structures in electrical contact with the conductive barrier material of the contact structures.

2. The microelectronic device of claim 1, wherein the conductive fill material directly contacts the conductive barrier material.

3. The microelectronic device of claim 1, wherein the conductive fill material directly contacts the conductive contact material.

4. The microelectronic device of claim 1, wherein the dielectric liner and the first interconnect liner extend substantially continuously to the conductive barrier material.

5. The microelectronic device of claim 1, wherein the dielectric liner and the first interconnect liner extend substantially continuously to the conductive contact material.

6. The microelectronic device of claim 1, wherein a width of the conductive fill material proximal to the contact structures is relatively less than a width of the conductive fill material distal to the contact structures.

7. The microelectronic device of claim 1, wherein a width of the conductive fill material proximal to the contact structures is substantially the same as a width of the conductive fill material distal to the contact structures.

8. The microelectronic device of claim 1, further comprising a portion of the source material between the dielectric liner of the interconnect structures and the conductive barrier material of the contact structures.

9. The microelectronic device of claim 8, wherein the portion of the source material extends horizontally between the dielectric liner of the interconnect structures and the conductive barrier material of the contact structures.

10. The microelectronic device of claim 9, wherein a portion of the horizontally extending source material comprises a metal silicide.

11. The microelectronic device of claim 10, wherein the conductive barrier material comprises tungsten silicide, the metal nitride material comprises titanium nitride, and the conductive contact material comprises tungsten.

12. The microelectronic device of claim 10, wherein the metal silicide is laterally adjacent to the source material.

13. A microelectronic device, comprising:
interconnect structures extending vertically through tiers of alternating oxide materials and conductive materials adjacent to a source material, the interconnect structures comprising a dielectric liner surrounding an interconnect liner and a conductive fill material; and
contact structures adjacent to and electrically coupled to the interconnect structures, the contact structures comprising one or more contact materials in direct contact with the conductive fill material of the interconnect structures, a relatively higher electrical resistivity material of the one or more contact materials in direct contact with the conductive fill material of the interconnect structures.

14. The microelectronic device of claim 13, wherein the conductive fill material contact structures are vertically adjacent to the interconnect structures.

15. The microelectronic device of claim 13, wherein the conductive fill material directly contacts a material of the one or more contact materials exhibiting a relatively lower electrical resistivity than the interconnect liner.

16. A method of forming a microelectronic device, comprising:
forming contact structures comprising one or more contact materials in a source material;
forming tiers of alternating oxide materials and conductive materials adjacent to the source material;
forming interconnect openings through the tiers of alternating oxide materials and conductive materials;
forming a dielectric liner and an interconnect liner within the interconnect openings;
removing a portion of the interconnect liner overlying the one or more contact materials of the contact structures; and
forming an interconnect fill material within the interconnect openings, the interconnect fill material directly contacting the one or more contact materials and the dielectric liner and the interconnect liner surrounding the interconnect fill material.

17. The method of claim 16, wherein forming contact structures comprising one or more contact materials in a source material comprises forming a conductive contact material, a metal nitride material, and a conductive barrier material in the source material.

18. The method of claim 16, wherein forming interconnect openings through the tiers of alternating oxide materials and conductive materials comprises extending a depth of the interconnect openings into the source material.

19. The method of claim 18, wherein forming an interconnect fill material within the interconnect openings comprises forming the interconnect fill material extending into the source material.

20. The method of claim 16, wherein forming an interconnect fill material within the interconnect openings comprises forming a portion of the interconnect fill material proximal to the one or more contact materials exhibiting a relatively lesser width than a portion of the interconnect fill material distal to the one or more contact materials.
